(19) United States
(12) Patent Application Publication
(10) Pub. No.: US 2026/0239616 A1
(43) Pub. Date: Aug. 13, 2026

(54) EMBEDDED MEMORY DEVICE AND METHOD OF FABRICATING THE SAME

(71) Applicant: TAIWAN SEMICONDUCTOR MANUFACTURING COMPANY, LTD., Hsinchu (TW)

(72) Inventors: Shih-Sian HUANG, Hsinchu (TW); Tai-Hao CHEN, Hsinchu (TW); Dian-Wei CHEN, Hsinchu (TW); Jin-Ying SONG, Hsinchu (TW)

(21) Appl. No.: 19/052,549

(22) Filed: Feb. 13, 2025

(51) Int. Cl. H10B 41/42; H10B 41/30; H10D 30/68

(52) U.S. Cl. CPC H10B 41/42; H10B 41/30; H10D 30/683; H10D 30/6892

(57) ABSTRACT

A method of fabricating a semiconductor device includes forming a first gate structure, a second gate structure, a third gate structure, and an insulating structure on a substrate such that the first gate structure, the second gate structure, the third gate structure, and the insulating structure have upper surfaces that are level with each other, wherein the insulating structure is between the first gate structure and the second gate structure; recessing the upper surfaces of the first and second gate structures relative to the upper surfaces of the third gate structure and the insulating structure; forming a cap structure on recessed surfaces of the first and second gate structures; removing the third gate structure to form an opening; and forming a replacement gate structure in the opening, including forming a conductive material in the opening and on upper surfaces of the cap structure on the first and second gate structures.

### BACKGROUND

Semiconductor devices with embedded memory are increasingly common. The embedded memory resides on a same die or substrate as other circuit structures such as logic. This integration of memory devices and logic devices involves fabrication of different device structures for the memory devices and the logic devices on a same die or substrate. However, a memory device can have a different structure from a logic device, such that fabrication operations to form one of the memory device or the logic device may not be optimal, or may be deleterious, for the formation of the other of the memory device or the logic device.

### BRIEF DESCRIPTION OF THE DRAWINGS

FIG. 1 is a plan view of a semiconductor device according to some embodiments.

FIG. 2 is a cross-sectional view of a semiconductor device according to some embodiments.

FIG. 3 is a cross-sectional view of a memory region of a semiconductor device according to some embodiments.

FIG. 4 is a cross-sectional view of a semiconductor device according to some embodiments.

FIG. 5 is a cross-sectional view of a semiconductor device according to some embodiments.

FIG. 6 is a flowchart of a method of fabricating a semiconductor device according to some embodiments.

FIGS. 7A, 7B, 7C, and 7D are cross-sectional flow diagrams of stages in a method of fabricating a semiconductor device according to some embodiments.

FIG. 8 is a flowchart of a method of fabricating a semiconductor device according to some embodiments.

FIGS. 9A, 9B, 9C, and 9D are cross-sectional flow diagrams of stages in a method of fabricating a semiconductor device according to some embodiments.

FIG. 10 is a block diagram of an IC device, according to at least one embodiment.
FIG. 11 is a block diagram of an electronic design automation (EDA) system in accordance with some embodiments.
FIG. 12 is a block diagram of an integrated circuit (IC) manufacturing system, and an IC manufacturing flow associated therewith, according to at least one embodiment.

### DETAILED DESCRIPTION

The following disclosure provides many different embodiments, or examples, for implementing different features of the provided subject matter. Specific examples of components, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device according to some embodiments includes a memory region and a logic region on a same substrate, e.g., a same die. According to some embodiments, dicing a wafer provides a plurality of dies each including a memory region and a logic region. Because the memory region and the logic region are formed on a same substrate, operations performed in fabricating memory device structures affect existing logic device structures, and operations performed in fabricating logic device structures affect existing memory device structures.

The integration of memory structures and logic structures on a same substrate thus entails selecting device structure designs, device materials, and/or fabrication operations that at least do not degrade parts of one device structure in the course of fabricating parts of another device structure. Conversely, the integration of memory structures and logic structures on a same substrate benefits from selecting device structure designs, device materials, and/or fabrication operations that facilitate fabrication of various device structures using simultaneous operations on both memory and device structures. At least some embodiments set forth herein provide for increased memory reliability when forming memory structures of embedded memory, i.e., memory structures on a same substrate as logic structures.

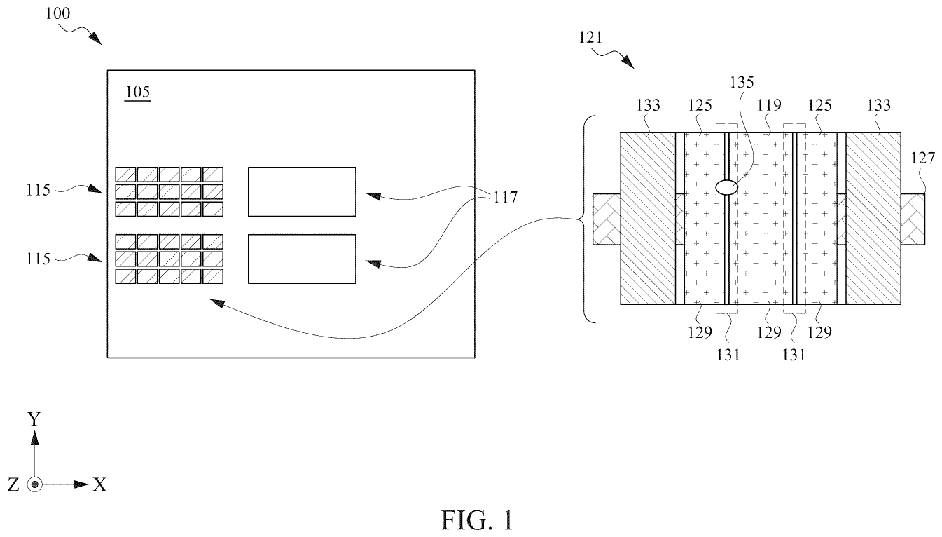

FIG. 1 is a plan view of a semiconductor device 100 according to some embodiments.

In FIG. 1, a region 105 of the semiconductor device 100 includes memory areas 115 and logic areas 117. Memory devices in the memory areas 115 are formed using at least some of the same operations that are used to form logic devices in the logic areas 117. The memory areas 115 may be referred to as embedded memory. In some embodiments, the embedded memory is implemented a volatile memory or a non-volatile memory (NVM). Examples of the non-volatile memory include flash memory such as NOR flash, NAND flash, and the like. An example flash memory structure is a split-gate flash memory.

In FIG. 1, two memory areas 115 are spaced apart in a first direction parallel to the X axis from two logic areas 117. The two memory areas 115 are separated from each other in a second direction parallel to the Y axis, and the two logic areas 117 are also separated from each other in the second direction. Although two memory areas 115 and two logic areas 117 are shown by way of example in FIG. 1, in other embodiments the semiconductor device includes one memory area 115 or more than two memory areas 115 and/or includes one logic area 117 and/or more than two logic areas 117. Further, the memory area(s) 115 and logic area(s) 117 are arranged in various arrangements in various embodiments, and are not limited to the arrangement shown in FIG. 1.

In fabricating the semiconductor device 100, operations performed in forming device structures such as transistors and the like in the logic areas 117 affect memory structures such as memory cells in the memory areas 115. Likewise, operations performed in forming memory structures such as memory cells in the memory areas 115 affect device structures such as transistors and the like in the logic areas 117. For example, a planarization operation such as CMP that is performed to planarize structures in the logic areas 117 also planarizes structures in the memory areas 115. As another example, in depositing a conductive material to form transistors in the logic areas 117, the conductive material is also deposited in the memory areas 115. As such, a situation can arise in which a planarization operation forms a scratch (which may be referred to as a microscratch) at an exposed surface of a memory structure in a memory area 115, and depositing a conductive material to form transistor gates or other conductive structures in the logic areas 117 also deposits the conductive material in the scratch in the memory area 115. In this situation, the conductive material-filled scratch can result in a scratch defect that unintentionally electrically connects adjacent, close-tolerance conductive structures in the memory area 115, potentially leading to a short-circuit between the adjacent conductive structures in the memory area 115. Such short-circuits can lead to poor reliability and/or increased power consumption, and thus are desirable to avoid.

In the example in FIG. 1, the semiconductor device 100 according to some embodiments includes a split-gate non-volatile memory (NVM) structure 121 in which a conductive erase gate structure 119 extends in the second direction across a semiconductor active region 127, e.g., an oxide-defined (OD) region. The active region 127 includes one or more fins, nanosheets, nanowires, or the like. The erase gate structure 119 has, on first and second sides thereof relative to the first direction, conductive control gate structures 125 that are, at least in part, at a same level (i.e., with reference to a third direction parallel to the Z axis) as the erase gate structure 119. The control gate structures 125 extend in the second direction alongside the erase gate structure 119. Select gate structures/wordlines 133 extend in the second direction alongside the control gate structures 125. The erase gate structure 119 and the control gate structures 125 each have a cap structure 129 on upper surface thereof.

The erase gate structure 119 and the adjacent control gate structures 125 have close-tolerance regions 131 therebetween. Label ‘135’ represents a possible location of a microscratch 135 that can be formed in some circumstances during fabrication of the semiconductor device 100, e.g., in connection with a CMP operation or other planarization operation (microscratch 135 is represented with dotted lines to indicate that a microscratch 135 may or may not be present). If a microscratch 135 were to be formed in a close-tolerance region 131, then the close-tolerance region 131 could be susceptible to bridging by conductive material that is unintentionally deposited in the microscratch 135 in the close-tolerance region 131. The cap structures 129 help to prevent the occurrence of microscratches 135, help to prevent conductive bridging, and help to prevent short-circuits, e.g., short-circuits between the erase gate structure 119 and the control gate structures 125. Such short-circuits can lead to poor reliability and/or increased power consumption, and thus are desirable to avoid.

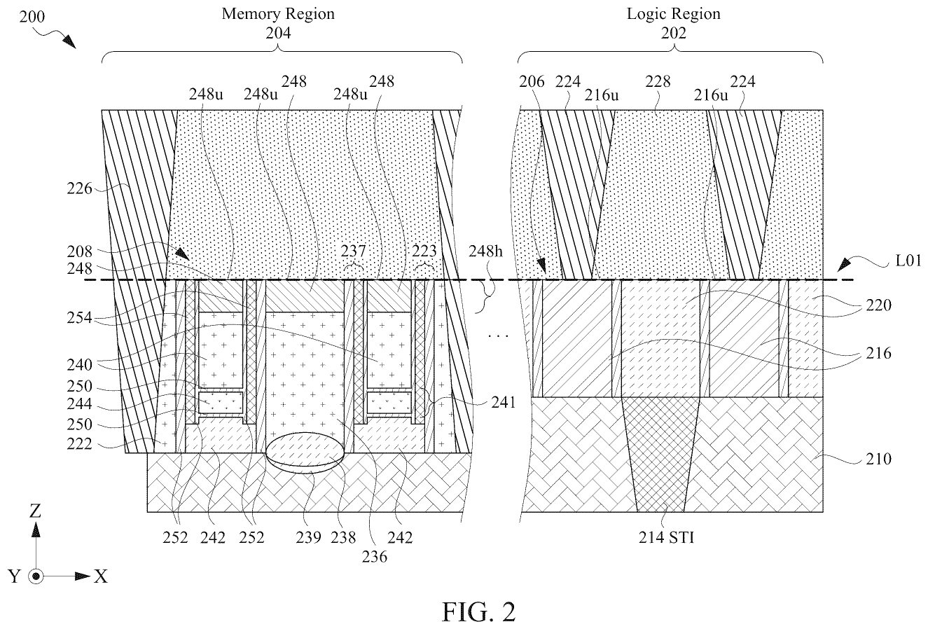

FIG. 2 is a cross-sectional view of a semiconductor device 200 according to some embodiments.

In FIG. 2, the semiconductor device 200 includes a logic region 202 and a memory region 204. The logic region 202 includes one or more transistors 206 implementing circuit structures such as an input/output (I/O) circuit, a static random-access memory (SRAM) circuit, a general logic (core) circuit, and the like. In some embodiments, the memory region 204 is an embedded memory that is formed on a same die area of substrate 210 as the logic region 202. The memory region 204 includes one or more memory devices 208. In FIG. 2, the memory device 208 is exemplified as a split-gate non-volatile memory (NVM) structure. The memory device(s) 208 can be used to implement, e.g., NOR flash memory, NAND flash memory, and the like. Memory devices other than a flash memory device can be used in addition to or instead of the split-gate NVM.

In FIG. 2, the logic region 202 includes two gate structures 216 on the substrate 210. In some embodiments, the two gate structures 216 are part of a same cell, e.g., a standard cell selected from a library of standard cells, and are included in a same circuit, e.g., a logic circuit that implements a logic gate or the like.

In some embodiments, the substrate 210 is a semiconductor substrate, e.g., a single-crystal substrate. In some embodiments, the substrate 210 is a silicon substrate, a silicon-germanium substrate, a silicon carbide substrate, a gallium arsenide substrate, or the like. In some embodiments, the substrate 210 includes silicon and another elemental semiconductor such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 210 is a semiconductor-on-insulator (SOI) substrate, e.g., a silicon-on-insulator substrate. In some embodiments, the substrate 210 includes a doped epitaxial (epi) layer, a gradient semiconductor layer, and/or a semiconductor layer overlying another semiconductor layer of a different type, such as a silicon layer on a silicon germanium layer. In some embodiments, the substrate 210 includes doped regions such as a p-well, an n-well, or both. In some embodiments, the substrate 210 is a dielectric substrate, a sapphire substrate, or the like.

The gate structures 216 in the logic region 202 include one or more conductive layers. In some embodiments, the gate structures 216 include polysilicon. In some embodiments, the gate structures 216 include metal or metal-containing layers. In some embodiments, the metal of the gate structures 216 is formed in a replacement metal gate (RMG) operation or the like, in which an initial sacrificial gate pattern of, e.g., polysilicon, is replaced with a metal such as aluminum, cobalt, copper, tungsten, or the like. In some embodiments, the gate structures 216 include, e.g., a work function layer including one or more of titanium nitride, tungsten, tantalum, nickel, platinum, ruthenium, molybdenum, aluminum, tungsten nitride, or the like, and a gate material layer including one or more of aluminum, cobalt, copper, tungsten, or the like, where the work function layer is selected from materials that are different from the gate material layer. A gate dielectric layer (not shown) at least partially surrounds the gate structures 216. In some embodiments, the gate dielectric layer is a high-k dielectric layer that includes one or more dielectric materials such as hafnium oxide, hafnium silicon oxide, hafnium silicon oxynitride, hafnium tantalum oxide, hafnium titanium oxide, hafnium zirconium oxide, metal oxides, metal nitrides, metal silicates, transition metal-oxides, transition metal nitrides, transition metal silicates, oxynitrides of metals, metal aluminates, zirconium silicate, zirconium aluminate, zirconium oxide, titanium oxide, aluminum oxide, a hafnium dioxide-alumina alloy, or the like. The gate structures 216 are each electrically coupled by a via 224 in, e.g., a via-gate (VG) layer, to one or more overlying conductive layers (not shown) in, e.g., a first metal layer (MO). The vias 224 include a conductive material, e.g., a metal such as aluminum, cobalt, copper, tungsten, or the like.

The gate structures 216 are spaced apart in the first direction. An isolation structure 214, e.g., a shallow trench isolation (STI) structure of a silicon oxide or the like, is formed in the substrate 210 between the gate structures 216. Although not shown in FIG. 2 for the sake of clarity, the logic region 202 also includes source/drain (S/D) regions corresponding to the gate structures 216, and contacts (e.g., metal-on-diffusion (MD) structures) on the S/D regions. Insulating structures 220, e.g., of a silicon oxide, silicon nitride, SiCN, SiON, SiOCN, SILK™, FOX™, HSQ, MSQ, Nanoglass™, HOSP, Black Diamond™, Coral™, Aurora™, or the like, are interspersed with the gate structures 216 relative to the first direction. An isolation layer 228 covers the gate structures 216 and the memory device(s) 208. The isolation layer 228 is a layer such as an ILD that includes one or more of SiNₓ, SiOₓ, SiON, SiC, SiCN, SiBN, SiCBN, BN, borophosphosilicate glass (BPSG), tetraethyl orthosilicate (TEOS), spin-on glass (SOG), undoped silicate glass (USG), fluorinated silicate glass (FSG), high-density plasma (HDP) oxide, plasma-enhanced TEOS (PETEOS), or the like.

The memory device 208 has a split-gate NVM structure that includes an erase gate structure 236 on the substrate 210, control gates structures 240 on either side of the erase gate structure 236 relative to the first direction, and floating gate structures 242 below the control gate structures 240 relative to the third direction. In some embodiments, the erase gate structure 236 and the control gate structures 240 are formed of a same conductive material. In some embodiments, the erase gate structure 236 and/or the control gate structures 240 include one or more conductive layers. In some embodiments, the erase gate structure 236, the control gate structures 240, and/or the floating gate structures 242 include polysilicon. In some embodiments, the erase gate structure 236 and/or the control gate structures 240 include a metal or metal-containing layers including one or more of aluminum, cobalt, copper, tungsten, or the like.

The control gate structures 240 are separated from the erase gate structure 236 relative to the first direction by respective insulating structures 237. The floating gate structures 242 are separated from the control gate structures 240 relative to the third direction by respective insulating structures 241. In some embodiments, the insulating structures 237 and/or the insulating structures 241 include a single layer of insulating material such as silicon oxide, silicon nitride, SiCN, SiON, SiOCN, SILK™, FOX™, HSQ, MSQ, Nanoglass™, HOSP, Black Diamond™, Coral™, Aurora™, or the like (herein, it will be understood that references to insulating materials, insulating structures, insulators, and the like encompass the use of dielectric materials unless stated otherwise or otherwise apparent). In other embodiments, the insulating structures 237 and/or the insulating structures 241 include two or more layers, e.g., a layer of silicon oxide on a side of the first gate structure, a layer of silicon nitride on a side of the silicon oxide layer, and another layer of silicon nitride on a side of the second gate structure, forming a silicon oxide/silicon nitride/silicon oxide structure between the first gate structure and the second gate structure. In FIG. 2, by way of example, the insulating structures 237 each include a pair of oxide layers 252 with a silicon nitride layer 254 therebetween relative to the first direction, and the insulating structures 241 each include a pair of oxide layers 250 with a silicon nitride layer 244 therebetween relative to the third direction.

In some embodiments, forming the cap structures 248 includes an etch-back operation, which removes upper regions of the erase gate structure 236 and control gate structures 240, a filling operation, which forms the cap structures 248 in the removed upper regions of the erase gate structure 236 and control gate structures 240, and a planarizing operation, which planarizes the memory region 204 and the logic region 202 to the first level L01. The cap structures 248 thus formed have heights 248h in the third direction, with upper extents thereof that are level with upper surfaces of the insulating structures 237 and 223, and level with the upper surfaces 216u of the gate structures 216 in the logic region 202. In some embodiments, the insulating structures 237 and/or insulating structures 223 serve as an etch stop or etch stop indicator. In other embodiments, another structure is included in one or more of the memory region 204 or the logic region 202 as a contact etch stop layer (CESL).

An NVM cell according to some embodiments includes a select gate structure 222, a control gate structure 240, a floating gate structure 242, and an erase gate structure 236. During a program operation, the electrons are injected to the floating gate structure 242 by a hot carrier injection (HCl) mechanism. During an erase operation, electrons move from the floating gate structure 242 to the erase gate structure 236 via a Fowler-Nordheim (FN) tunneling mechanism.

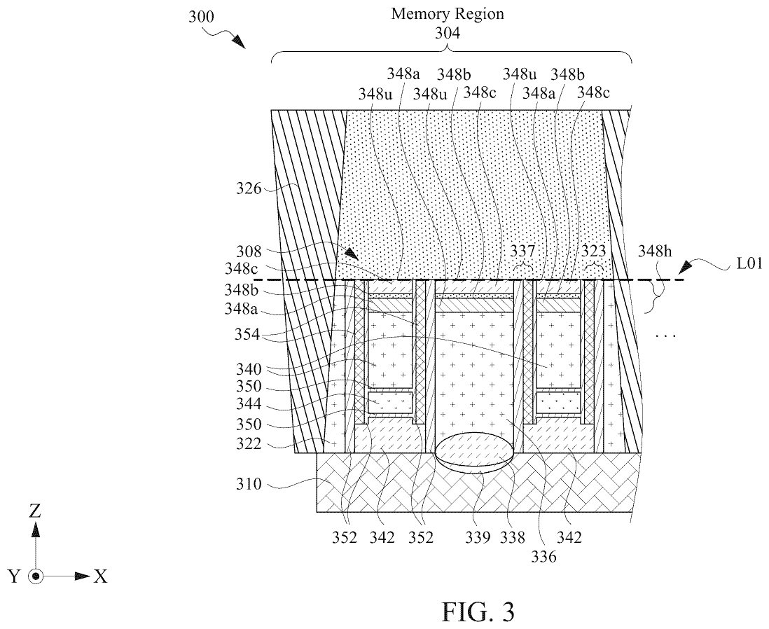

Upper surfaces of the erase gate structure 236 and the control gate structures 240 are covered by cap structures 248. The cap structures 248 are or include an insulator. In some embodiments, the cap structures are a monolithic structure of an electrically insulating material. In some embodiments, the cap structures 248 include an electrically insulating material at an upper surface 248u thereof. The cap structures 248 on the erase gate structure 236 and the control gate structures 240 help to protect and insulate the erase gate structure 236 and the control gate structures 240. In FIG. 2, by way of example, the cap structures 248 are a single layer of material, e.g., a single layer of an electrically insulating material that is or includes one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)). In other embodiments, the cap structures 248 include two or more material layers (an example of a cap structure that includes two or more material layers is described below in connection with FIG. 3).

The cap structures 248 help to prevent a conductive material deposited over the memory device 208 during fabrication of structures in the logic region 202 from coming into contact with the conductive material of the erase gate structure 236 and the control gate structures 240, thus helping to prevent short-circuits between the erase gate structure 236 and the control gate structures 240.

In another approach, a cap structure is not used on the memory-region gate structures. In the other approach, conductive material that is deposited in the logic region 202, e.g., in a RMG-forming operation for the gate structures 216, can also be deposited in microscratches in the memory region 204, e.g., between the erase gate structure 236 and the control gate structures 240, possibly forming a conductive bridge between the erase gate structure 236 and the control gate structures 240 to result in a short-circuit, leading to poor reliability and/or increased power consumption.

In some embodiments, a material that forms the cap structures 248 is selected to be more hydrophilic than a material that forms the underlying erase gate structure 236 and/or control gate structures 240. In some embodiments, a material that forms upper surfaces 248u of the cap structures 248 is selected to be more hydrophilic than a material that forms the underlying erase gate structure 236 and/or control gate structures 240.

In some embodiments, the erase gate structure 236 and the control gate structures 240 are recessed, e.g., using an etch-back operation or the like, and replaced with one or more materials forming the cap structures 248, the materials forming the cap structures being more hydrophilic than the materials of the erase gate structure 236 and the control gate structures 240.

In other embodiments, the uppermost surfaces of the erase gate structure 236 and the control gate structures 240 are processed (e.g., by reaction with a chemical agent and/or physical processing) to make the uppermost surfaces of the erase gate structure 236 and the control gate structures 240 more hydrophilic than the interior of the erase gate structure 236 and the control gate structures 240, the more-hydrophilic upper surfaces thus serving as the cap structures 248. In some embodiments, such processing includes one or more of a chemical reaction and/or treatment of the uppermost surfaces of the erase gate structure 236 and the control gate structures 240 with, e.g., a solution of ammonium hydroxide and hydrogen peroxide or a plasma such as an oxygen-containing plasma or hydrogen peroxide plasma, to increase the hydrophilicity of the uppermost surfaces of the erase gate structure 236 and the control gate structures 240. In some embodiments, the interior of the erase gate structure 236 and the control gate structures 240 have materials and/or chemical elements in common with the more hydrophilic cap structures 248.

In some embodiments, providing a more hydrophilic cap structure 248 or a more hydrophilic upper surface 248u makes it easier to clean the device during fabrication. By selecting the material that forms the cap structures 248 to be more hydrophilic than a material, e.g., polysilicon, that forms the underlying erase gate structure 236 and/or control gate structures 240, particles are less likely to bind or stick to the cap structures 248, e.g., relative to a more hydrophobic material and/or relative to a gate material that is covered by the cap structures 248. Further, by selecting the material that forms the cap structures 248 to be more hydrophilic than a material, e.g., polysilicon, that forms the underlying erase gate structure 236 and/or control gate structures 240, a cleaning operation performed during fabrication of the semiconductor device 200 can more effectively remove particles and/or foreign materials (e.g., relative to removal from polysilicon), thus helping to reduce scratching and the like, and thus helping to prevent-short circuits between the erase gate structure 236 and the control gate structures 240.

In some embodiments, a material that forms the cap structures 248 is selected to be harder than a material that forms the underlying erase gate structure 236 and/or control gate structures 240. In some embodiments, a material that forms the upper surfaces 248u of the cap structures 248 is selected to be harder, or the upper surfaces 248u are processed to be harder, relative to a material that forms the underlying erase gate structure 236 and/or control gate structures 240.

In some embodiments, the erase gate structure 236 and the control gate structures 240 are recessed, e.g., using an etch-back operation or the like, and replaced with one or more materials forming the cap structures 248, the materials forming the cap structures being harder than the materials of the erase gate structure 236 and the control gate structures 240.

In other embodiments, the uppermost surfaces of the erase gate structure 236 and the control gate structures 240 are processed (e.g., by reaction with a chemical agent and/or physical processing) to make the uppermost surfaces of the erase gate structure 236 and the control gate structures 240 harder than the interior of the erase gate structure 236 and the control gate structures 240, the harder upper surfaces thus serving as the cap structures 248. In some embodiments, such processing includes one or more of a chemical reaction and/or treatment of the uppermost surfaces of the erase gate structure 236 and the control gate structures 240 to increase the hardness of the uppermost surfaces of the erase gate structure 236 and the control gate structures 240. In some embodiments, the interior of the erase gate structure 236 and the control gate structures 240 have materials and/or chemical elements in common with the harder cap structures 248.

In some embodiments, providing a harder cap structure 248 or a harder upper surface 248u makes it less likely that microscratches will be formed during device fabrication. By selecting the material that forms the cap structures 248, e.g., a metal, to be harder than a material that forms the underlying erase gate structure 236 and/or control gate structures 240, e.g., polysilicon, particles are less likely to be adsorbed and scratches are less likely to be formed. Reducing such scratches reduces the possibility of conductive material, deposited in a later fabrication operation, from filling the scratches and creating conductive bridges or short circuits between the erase gate structure 236 and the control gate structures 240.

In FIG. 2, the upper surfaces 248u of the cap structures 248 in the memory region 204 are at a same level L01 as upper surfaces 216u of the gate structures 216 in the logic region 202. In some embodiments, forming memory devices 208 in the memory region 204 and forming the transistors 206 in the logic region 202 includes planarizing (e.g., using CMP or the like) the cap structures 248 and the gate structures 216 in a same planarizing operation, such that the upper surfaces 248u of the cap structures 248 and the upper surfaces 216u of the gate structures are substantially even with or level with each other, as indicated by level L01.

In the memory region 204, select gate structures 222 are at outer sides of the control gate structures 240 relative to the first direction, and are electrically coupled to word line contact structures 226. In some embodiments, the select gate structures 222 are formed of a same conductive material as the erase gate structure 236 and/or the control gate structures 240. In some embodiments, the select gate structures 222 include one or more conductive layers. In some embodiments, the select gate structures 222 include polysilicon. In some embodiments, the select gate structures 222 include a metal or metal-containing layers including one or more of aluminum, cobalt, copper, tungsten, or the like. The word line contact structures 226 include, e.g., one or more of aluminum, cobalt, copper, tungsten, or the like.

The select gate structures 222 are separated from the control gate structures 240 relative to the first direction by respective insulating structures 223. In some embodiments, the insulating structures 223 include a single layer of insulating material such as silicon oxide, silicon nitride, SiCN, SiON, SiOCN, SILK™, FOX™, HSQ, MSQ, Nanoglass™, HOSP, Black Diamond™, Coral™, Aurora™, or the like. In other embodiments, the insulating structures 223 include two or more layers, e.g., a layer of silicon oxide on a side of the first gate structure, a layer of silicon nitride on a side of the silicon oxide layer, and another layer of silicon nitride on a side of the second gate structure, forming a silicon oxide/silicon nitride/silicon oxide structure between the first gate structure and the second gate structure. In FIG. 2, by way of example, the insulating structures 223 each include a pair of oxide layers 252 with a silicon nitride layer 254 therebetween relative to the first direction.

Drain regions (not shown) are at outer sides of the control gate structures 240 relative to the first direction, and a common source region 239 is in the substrate 210 below the erase gate structure 236. The common source region 239 is isolated from the erase gate structure 236 by an isolation region 238 of, e.g., an oxide or a multi-layer oxide film.

FIG. 3 is a cross-sectional view of a memory region of a semiconductor device 300 according to some embodiments.

FIG. 3 illustrates a memory region 304 according to some embodiments, which may be used instead of the memory region 204 of FIG. 2 in one or more regions of the semiconductor device 300. In FIG. 3, the logic region 202 is not shown to avoid repetition but will be understood to be included in the semiconductor device 300, as in FIG. 2. Elements of semiconductor device 300 having a similar structure and function as elements of semiconductor device 200 in the description of FIG. 2 have a same identifying numeral, incremented by 100, unless stated otherwise or otherwise apparent.

In FIG. 3, a memory device 308 in the memory region 304 has a split-gate NVM structure that includes an erase gate structure 336 on a substrate 310, control gates structures 340 on either side of the erase gate structure 336 relative to the first direction, and floating gate structures 342 below the control gate structures 340. In some embodiments, the erase gate structure 336 and the control gate structures 340 are formed of a same conductive material. In some embodiments, the erase gate structure 336 and the control gate structures 340 include one or more conductive layers. In some embodiments, the erase gate structure 336, the control gate structures 340, and/or the floating gate structures 342 include polysilicon. In some embodiments, the erase gate structure 336 and the control gate structures 340 include a metal or metal-containing layers including one or more of aluminum, cobalt, copper, tungsten, or the like.

The memory device 308 includes a cap structure 348. By way of example, the cap structure 348 is shown as a three-layer structure that includes a first layer 348a of an electrically insulating material on underlying erase and control gate structures 336, 340, a second layer 348b of an adhesive material on the first layer 348a, and a third layer 348c of a metal on the second layer 348b. In some embodiments, the electrically insulating material of the first layer 348a is or includes one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)). In some embodiments, the adhesive material of the second layer 348b is or includes one or more of a metal and/or a metal nitride, e.g., titanium, titanium nitride, tantalum, and/or tantalum nitride. In some embodiments, the adhesive material layer of the second layer 348b is itself a multilayer (not shown in FIG. 3), e.g., a metal nitride layer on the insulating material layer and a metal layer on the metal nitride layer. Particular examples of the second layer 348b include a bilayer of titanium nitride/titanium stack, a tantalum nitride/tantalum stack, and the like. In some embodiments, the second layer 348b further includes an interfacial metal oxide of the metal, e.g., titanium, tantalum, or the like, e.g., in an ordered stack of nitride/oxide/metal, with the nitride being the first-formed layer on the first layer of the insulating material. In some embodiments, the metal layer formed as the third layer 348c includes one or more of aluminum, cobalt, copper, tungsten, or the like.

In some embodiments, the third layer 348c includes at least one metal or metal-containing layer that is also included in the gate structures 216 in the logic region 202 (refer to FIG. 2). That is, in some embodiments, metal or metal-containing layers that are deposited to form the gate structure(s) 216 in the logic region 202 are at the same time deposited on the second layer 348b to form the third layer 348c.

In some embodiments, a material that forms the third layer 348c is selected to be more hydrophilic than a material that forms the underlying erase gate structure 336 and/or control gate structures 340. In some embodiments, a material that forms an upper surface 348u of the third layer 348c is more hydrophilic than a material that forms the underlying erase gate structure 336 and/or control gate structures 340. In some embodiments, a more hydrophilic third layer 348c and/or a more hydrophilic upper surface 348u is easier to clean. By selecting the material that forms the third layer 348c (or upper surface 348u) to be more hydrophilic than the material that forms the underlying erase gate structure 336 and/or control gate structures 340, a cleaning operation performed during fabrication of the semiconductor device 300 can more effectively remove particles and/or foreign materials, thus helping to reduce scratching and the like.

In some embodiments, a material that forms the third layer 348c is selected to be harder than a material that forms the underlying second layer 348b. In some embodiments, a material that forms the upper surface 348u of the third layer 348c is selected to be harder, or the upper surface 348u is processed to be harder, relative to a material that forms the underlying second layer 348b. Providing a harder cap structure 348 and/or a harder upper surface 348u makes it less likely that microscratches will be formed during device fabrication. By selecting the material that forms the third layer 348c (or upper surface 348u) to be harder, scratches are less likely to be formed at the upper surface 348u.

As noted above, the logic region 202 of FIG. 2 is included in the semiconductor device 300, as in FIG. 2. Referring to FIGS. 2 and 3, the upper surface 348u of the third layer 348c in the memory region 304 is at the same level L01 as upper surfaces 216u of the gate structures 216 in the logic region 202 (refer to FIG. 2). In some embodiments, forming memory devices 308 in the memory region 304 and forming the transistors 206 in the logic region 202 includes planarizing (e.g., using CMP or the like) the third layer 348c and the gate structures 216 in a same planarizing operation, such that the upper surface 348u of the third layer 348c and the upper surfaces 216u of the gate structures are substantially even with or level with each other, as indicated by level L01.

In some embodiments, forming the cap structures 348 includes an etch-back operation, which removes upper regions of the erase gate structure 336 and the control gate structures 340, a filling operation, which forms the first, second, and third layers 348a, 348b, 348c in the removed upper regions of the erase gate structure 336 and control gate structures 340, and a planarizing operation, which planarizes the memory region 304 and the logic region 302 to the first level L01. The cap structures 348 thus formed have heights 348h in the third direction, with upper extents thereof that are level with upper surfaces of the insulating structures 337 and 323, and level with the upper surfaces 216u of the gate structures 216 in the logic region 202. In some embodiments, heights of the cap structures 348 are formed to be the same as heights of the cap structures 248 described above. In some embodiments, the insulating structures 337 and/or insulating structures 323 serve as an etch stop or etch stop indicator. In other embodiments, another structure is included in one or more of the memory region 204 or the logic region 202 as a contact etch stop layer (CESL).

It will be appreciated that the features and operations described in connection with the semiconductor device 200 are usable singly or in combination with features and operations described in connection with the semiconductor device 300. Thus, for example, a single-layer cap structure and a multi-layer cap structure can be implemented on a same die or substrate. Also, although three layers (348a, 348b, 348c) for the cap structures 348 are described in connection with FIG. 3, the number of layers can be one, two, or greater than three. Increasing the number of layers can provide greater device design freedom and provide opportunities to further enhance device performance, but involves more operations and can increase costs and/or impact thermal budget. Thus, for example, the cap structure 348 can be implemented with an uppermost surface that is a metal in some embodiments, thereby providing greater scratch resistance than a cap structure 248 implemented with a softer electrically insulating material. Conversely, more operations are involved in fabricating the cap structure 348 as compared to the cap structure 248.

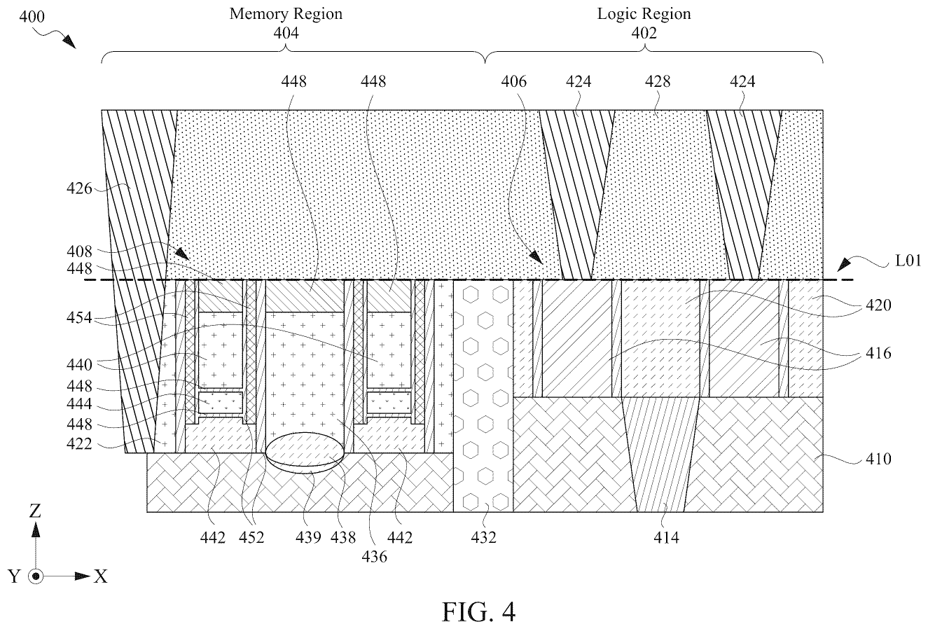

FIG. 4 is a cross-sectional view of a semiconductor device 400 according to some embodiments.

The semiconductor device 400 is a variation of the semiconductor device 200. Elements of semiconductor device 400 having a similar structure and function as elements of semiconductor device 200 in the description of FIG. 2 have a same identifying numeral, incremented by 200, unless stated otherwise or otherwise apparent.

The semiconductor device 400 has memory region 404 abutting logic region 402 at a dummy structure 432. In some embodiments, the dummy structure 432 is formed of a same material as a gate in the memory region 404 or the logic region 402, while being electrically isolated from other circuit structures or being electrically connected but floated. In some embodiments, the dummy structure 432 is a dummy gate that is formed of a sacrificial material, e.g., polysilicon or the like. In some embodiments, the dummy structure 432 is at a cell boundary of a layout. The cell boundary divides a memory cell, which includes memory device 408, from an adjacent logic cell, which includes transistors 406 implementing circuit structures such as an input/output (I/O) circuit, a static random-access memory (SRAM) circuit, a general logic (core) circuit, and the like.

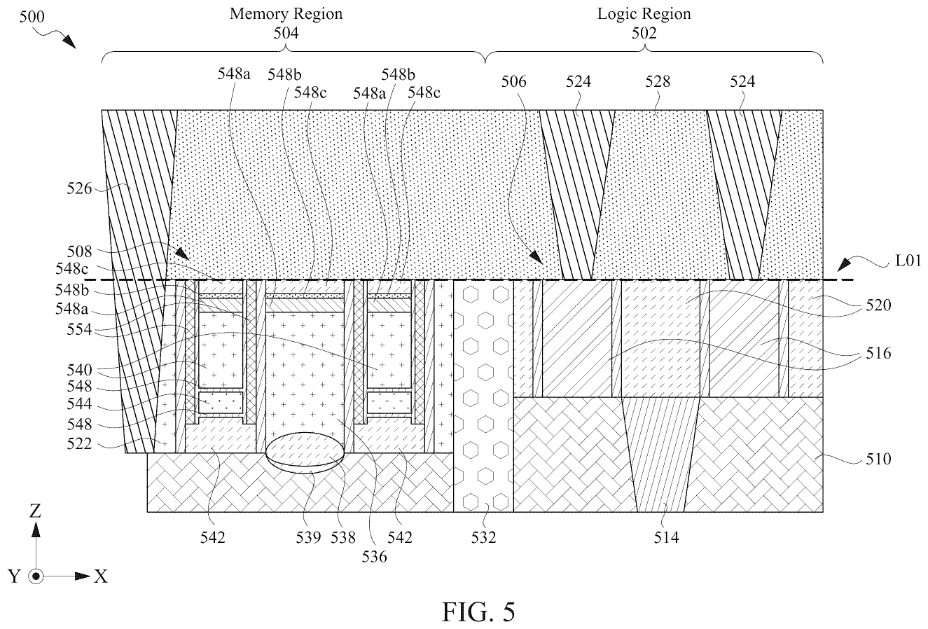

FIG. 5 is a cross-sectional view of a semiconductor device 500 according to some embodiments.

The semiconductor device 500 is a variation of the semiconductor device 300. Elements of semiconductor device 500 having a similar structure and function as elements of semiconductor device 300 in the description of FIG. 3 have a same identifying numeral, incremented by 200, unless stated otherwise or otherwise apparent.

The semiconductor device 500 has memory region 504 abutting logic region 502 at a dummy structure 532. In some embodiments, the dummy structure 532 is formed of a same material as a gate in the memory region 504 or the logic region 502, while being electrically isolated from other circuit structures or being electrically connected but floated. In some embodiments, the dummy structure 532 is a dummy gate that is formed of a sacrificial material, e.g., polysilicon or the like. In some embodiments, the dummy structure 532 is at a cell boundary of a layout. The cell boundary divides a memory cell, which includes memory device 508, from an adjacent logic cell, which includes transistors 506 implementing circuit structures such as an input/output (I/O) circuit, a static random-access memory (SRAM) circuit, a general logic (core) circuit, and the like.

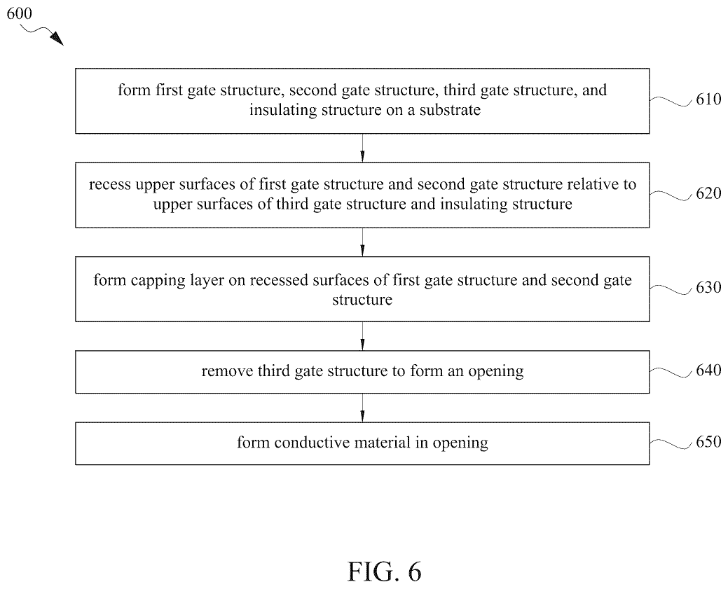

FIG. 6 is a flowchart of a method 600 of fabricating a semiconductor device according to some embodiments.

In FIG. 6, the method 600 includes operations 610, 620, 630, 640, and 650. Although the operations are numbered in sequence, the operations are not to be construed as necessarily requiring their performance in the particular order discussed or illustrated. Moreover, additional or alternative operations can be performed.

Referring to FIG. 6, operation 610 includes forming a first gate structure, a second gate structure, a third gate structure, and an insulating structure on a substrate.

In some embodiments, the substrate is a semiconductor substrate, e.g., a single crystal substrate. In some embodiments, the substrate is a silicon substrate, a silicon-germanium substrate, a silicon carbide substrate, a gallium arsenide substrate, or the like. In some embodiments, the substrate includes silicon and another elemental semiconductor such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate is a semiconductor-on-insulator (SOI) substrate, e.g., a silicon-on-insulator substrate. In some embodiments, the substrate includes a doped epi layer, a gradient semiconductor layer, and/or a semiconductor layer overlying another semiconductor layer of a different type, such as a silicon layer on a silicon germanium layer. In some embodiments, the substrate includes doped regions such as a p-well, an n-well, or both. In some embodiments, the substrate is a dielectric substrate, a sapphire substrate, or the like.

In some embodiments, the first gate structure, the second gate structure, and the third gate structure are formed of a same conductive material. In some embodiments, the first gate structure, the second gate structure, and/or the third gate structure are formed of one or more conductive layers. In some embodiments, the first gate structure, the second gate structure, and the third gate structure are formed of polysilicon or the like. In some embodiments, the first gate structure and/or the second gate structure are formed of a metal or metal-containing layers including one or more of aluminum, cobalt, copper, tungsten, or the like. In some embodiments, the third gate structure is formed of a sacrificial material, e.g., polysilicon, amorphous silicon, or the like, that will be replaced with a functional conductive gate material such as a metal.

In some embodiments, the insulating structure is formed as a single layer of insulating material. In other embodiments, the insulating structure is formed of two or more layers, e.g., a layer of silicon oxide on a side of the first gate structure, a layer of silicon nitride on a side of the silicon oxide layer, and another layer of silicon nitride on a side of the second gate structure, forming a silicon oxide/silicon nitride/silicon oxide structure between the first gate structure and the second gate structure.

In some embodiments, forming the first gate structure, the second gate structure, the insulating structure, and the third gate structure includes planarizing (e.g., using CMP or the like) upper surfaces of the first gate structure, the second gate structure, the insulating structure, and the third gate structure such that all four of the first gate structure, the second gate structure, the insulating structure, and the third gate structure have upper surfaces that are substantially even with or level with each other.

In some embodiments, the first gate structure, the second gate structure, and the insulating structure are formed in a memory region of the substrate. In some embodiments, the first gate structure, the second gate structure, and the insulating structure are all part of a same memory device, e.g., an NVM memory device such as a split-gate flash memory device or the like.

In some embodiments, the third gate structure is in a logic region of the substrate, and is spaced apart from the first and second gate structures. In some embodiments, the third gate structure corresponds to a location of a replacement gate, e.g., a replacement metal gate (RMG), in a transistor that forms a circuit in the logic region.

In some embodiments, operation 610 also includes forming a fourth gate structure as part of the memory device, on an opposite side of the first gate structure from the second gate structure. In some embodiments, the first gate structure corresponds to an erase gate of a split-gate memory device, and the second and fourth gate structures correspond to control gates of the split-gate memory device. In some embodiments, the second and fourth gate structures are formed over respective floating gate structures of the split-gate memory device.

Operation 620 includes recessing upper surfaces of first gate structure and second gate structure relative to upper surfaces of third gate structure and insulating structure.

In some embodiments, a masking layer is deposited and then patterned to form an opening or openings in the masking layer corresponding to locations of the first and second gate structures. In some embodiments, the masking layer is or includes a photoresist layer. An etching operation, e.g., an isotropic or anisotropic etching operations such as a wet etch, plasma etch, or the like, is performed to partially remove the first and second gate structures through the opening(s) in the masking layer. In some embodiments, the masking layer includes a single opening that exposes upper surfaces of the first and second gate structures and the insulating structure while covering the third gate structure. In other embodiments, the masking layer is patterned to expose upper surfaces of the first and second gate structures while covering the insulating structure and the third gate structure.

In some embodiments, the etching operation reduces overall height of the first and second gate structures (i.e., height in the z-axis direction) by about 10% of the height of the first gate structure and/or the second gate structure, e.g., about 10% of the height of the shorter one of the first gate structure and the second gate structure. In a particular example, the first gate structure corresponds to an erase gate, the second gate structure corresponds to a control gate, the first gate structure has an overall height that is greater than that of the second gate structure (while having an upper surface that is level with an upper surface of the second gate structure), and an etching operation is performed to recess each of the first gate structure and the second gate structure by about 10% of the overall height of the second (shorter) gate structure. High percentages of etch-back, e.g., 50% of the overall height, can result in a gate structure that is small and has a sheet resistance that is high, which can impact device performance.

In some embodiments, a single continuous opening is formed in the masking layer to expose the first gate structure, the second gate structure, and the insulating layer to an etchant, and an etchant (e.g., an isotropic etchant) that is used to recess the first gate structure and the second gate structure is selective towards a material included in the first gate structure and the second gate structure relative to a material included in the insulating structure such that the insulating structure is not removed or is removed at a lesser rate than the first gate structure and the second gate structure. In a particular example, the insulating structure protrudes (in the Z-axis direction) above the first gate structure and the second gate structure following the etching operation. In other embodiments, an anisotropic etching operation is performed to recess the first gate structure and the second gate structure.

In some embodiments, operation 620 also includes recessing the upper surface of the fourth gate structure, e.g., by about 10% of the height of the fourth gate structure.

In some embodiments, the masking layer is removed following the etching operation, e.g., completely removed, or removed from a memory region of the substrate while being allowed to fully or partially remain in a logic region of the substrate.

Operation 630 includes forming a cap structure on the recessed upper surfaces of first gate structure and second gate structure.

Forming the cap structure includes depositing a material on the recessed surfaces of the first gate structure and the second gate structure. In some embodiments, a material is deposited on the recessed surfaces of the first and second gate structures and covering the insulating structure between the first gate structure and the second gate structure, and then planarized to expose the insulating structure. In other embodiments, a material is deposited on the recessed surfaces of the first and second gate structures, and across the surface of the substrate so as to cover the insulating structure between the first gate structure and the second gate structure and cover the third gate structure, and then planarized to expose the insulating structure and the third gate structure.

In some embodiments, a single layer of material is deposited on the recessed surfaces of the first gate structure and the second gate structure, e.g., a single layer of an electrically insulating material that is or includes one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)).

In some embodiments, operation 630 also includes forming the cap structure on the recessed upper surface of the fourth gate structure.

Operation 640 includes removing the third gate structure to form an opening.

In some embodiments, removing the third gate structure includes forming a masking layer and patterning the masking layer to form an opening at a location in the masking layer corresponding to the location of the third gate structure. The masking layer covers the cap structure on the first and second gate structures. An etching operation, e.g., an isotropic or anisotropic etching operations such as a wet etch, plasma etch, or the like, is performed to remove the third gate structure through the opening in the masking layer.

In some embodiments, operation 640 also includes forming the masking layer to cover the cap structure on the fourth gate structure.

In some embodiments, the masking layer is removed following the etching operation, e.g., completely removed, or removed from the logic region of the substrate while being allowed to fully or partially remain in the memory region of the substrate.

Operation 650 includes forming a conductive material in the opening corresponding to the third gate structure.

In some embodiments, the conductive material is or includes a metal, and a replacement metal gate (RMG) is formed in the opening where the third gate structure was removed. In some embodiments, the RMG includes one or more metal or metal-containing layers, e.g., a work function layer including one or more of titanium nitride, tungsten, tantalum, nickel, platinum, ruthenium, molybdenum, aluminum, tungsten nitride, or the like, and a gate material layer including one or more of aluminum, cobalt, copper, tungsten, or the like, where the work function layer is selected from materials that are different from the gate material layer. In some embodiments, prior to forming the RMG, a gate dielectric layer such as a high-k dielectric layer is formed in the opening where the third gate structure was removed. In some embodiments, the high-k dielectric layer includes one or more dielectric materials such as hafnium oxide, hafnium silicon oxide, hafnium silicon oxynitride, hafnium tantalum oxide, hafnium titanium oxide, hafnium zirconium oxide, metal oxides, metal nitrides, metal silicates, transition metal-oxides, transition metal nitrides, transition metal silicates, oxynitrides of metals, metal aluminates, zirconium silicate, zirconium aluminate, zirconium oxide, titanium oxide, aluminum oxide, a hafnium dioxide-alumina alloy, or the like.

In some embodiments, operation 650 includes forming the conductive material after the masking layer is completely removed, such that the conductive material fills the opening where the third gate structure was removed and covers the substrate in the logic and memory regions, thus covering the cap structure on the first and second gate structures. The substrate is then planarized to expose the cap structure on the first and second gate structures.

In the method 600, operations 620 and 630 of recessing the first and second gate structures and the forming of the cap structure, which is or includes an insulator, on the first and second gate structures helps to prevent the conductive material layer formed in operation 650 from coming into contact with the material, e.g., polysilicon or the like, of the first and second gate structures, thus helping to prevent short-circuits, e.g., between the first and second gate structures.

In some embodiments, operations 620 and 630 include recessing the first, second, and fourth gate structures and forming of the cap structure, which is or includes an insulator, on the first, second, and fourth gate structures, which helps to prevent the conductive material layer formed in operation 650 from coming into contact with the material, e.g., polysilicon or the like, of the first and second gate structures and/or the first and fourth gate structures, thus helping to prevent short-circuits, e.g., between the first and second gate structures and/or the first and fourth gate structures.

In another approach, the cap structure is not used on the memory-region gate structures, e.g., on the first and second gate structures or on the first, second, and fourth gate structures. In the other approach, conductive material that is deposited in a RMG-forming operation for the third gate structure in the logic region can also be deposited in microscratches in the memory region e.g., between the first and second gate structures (or between the first and fourth gate structures), and thus possibly form a conductive bridge between the first and second gate structures (or between the first and fourth gate structures) to result in a short-circuit.

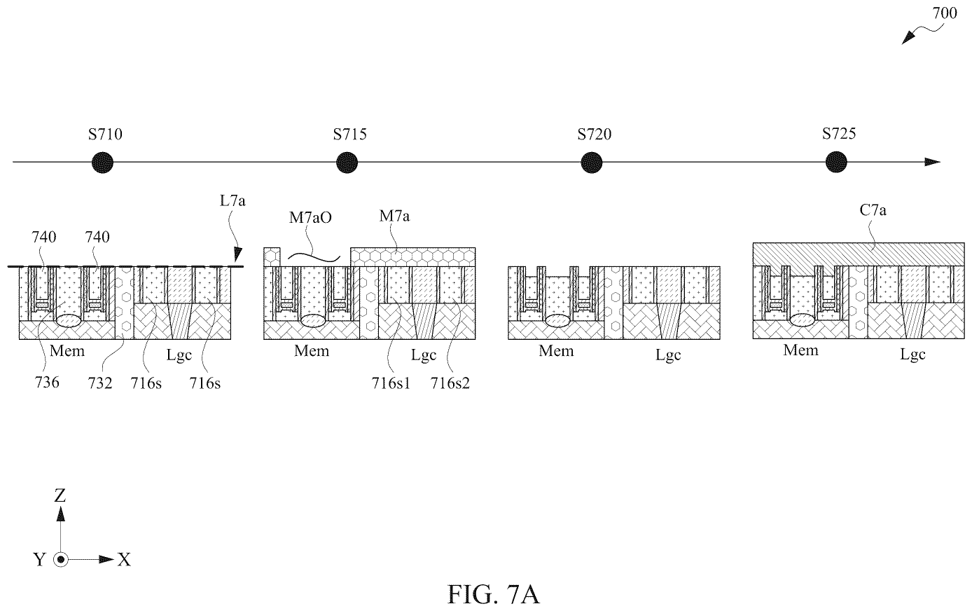

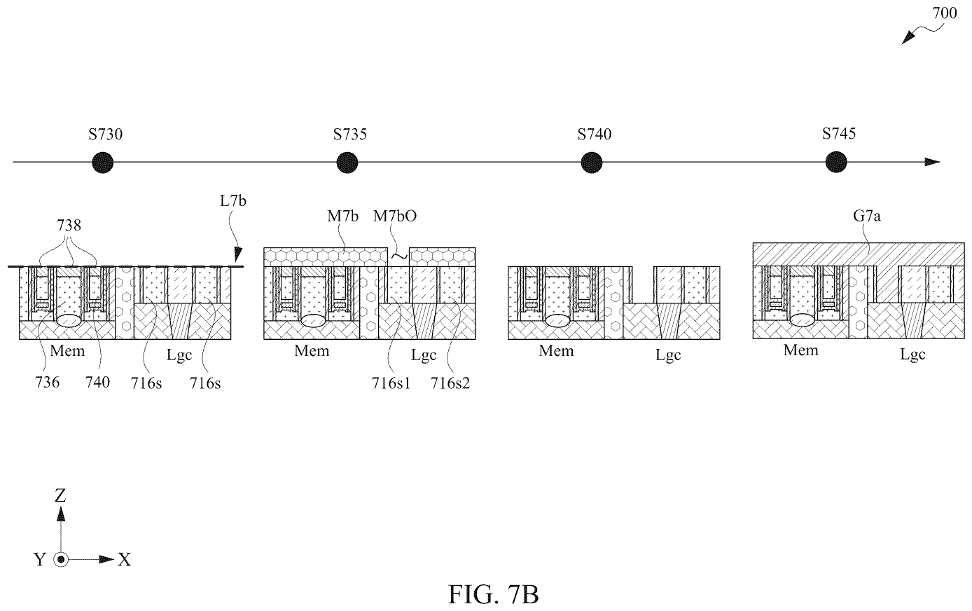

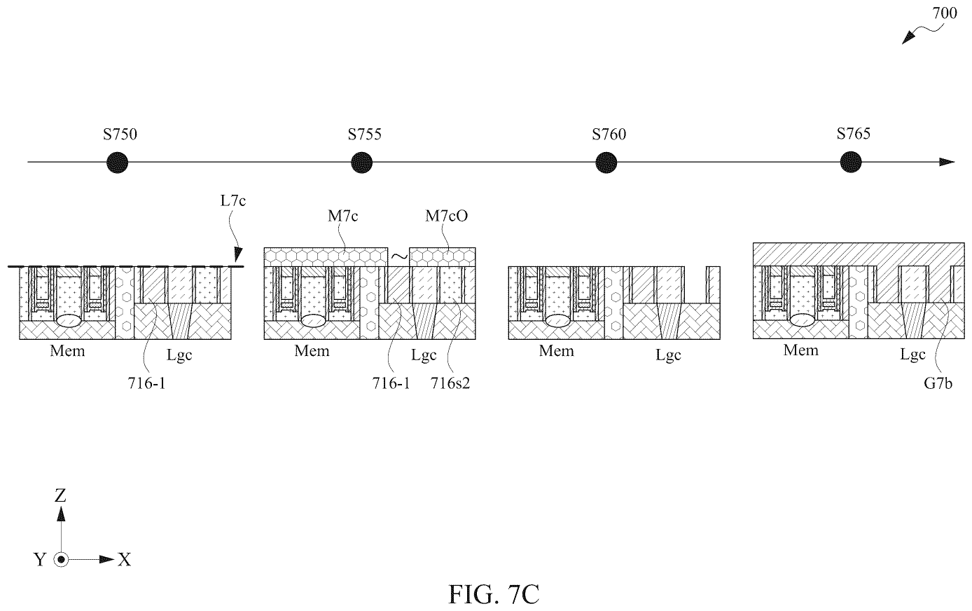

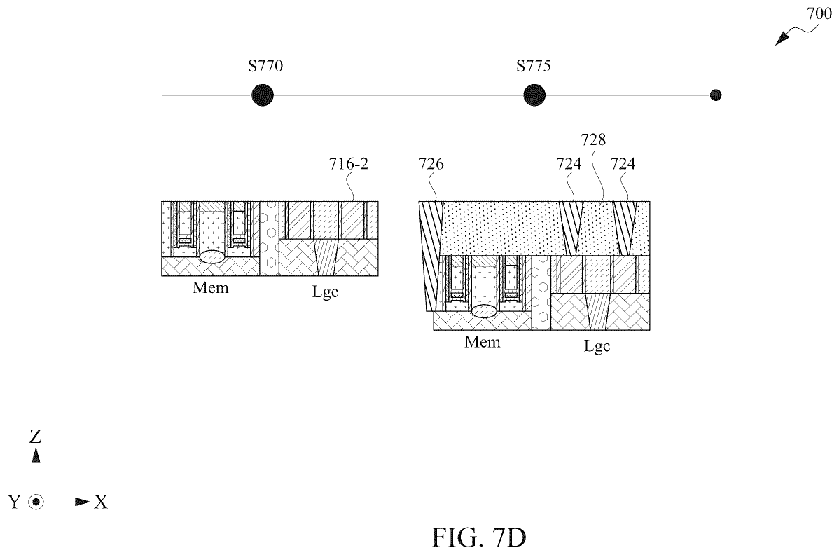

FIGS. 7A, 7B, 7C, and 7D are cross-sectional flow diagrams of stages in a method 700 of fabricating a semiconductor device, e.g., the semiconductor device 400, according to some embodiments.

FIG. 7A includes stages S710, S715, S720, and S725. FIG. 7B includes stages S730, S735, S740, and S745. FIG. 7C includes stages S750, S755, S760, and S765. FIG. 7D includes stages S770 and S775.

Referring to FIG. 7A, in stage S710, a first planarization operation, e.g., CMP or the like, is performed to provide an intermediate semiconductor device structure that includes gate structures in a memory cell (‘Mem’) and gate structures in a logic cell (‘Lgc’) that abut a common dummy structure 732. The memory cell includes an erase gate structure 736 and control gate structures 740. The logic cell includes sacrificial gate structures 716s that correspond to locations where gate structures will be formed in the logic cell, e.g., for P-type and/or N-type transistors in a CMOS circuit.

In FIG. 7A, the erase gate structure 736, the control gate structures 740, and the sacrificial gate structures 716s are formed of a same conductive material, e.g., polysilicon or the like. As will be described, in later stages of the method 700 the sacrificial gate structures 716s are removed and replaced with a conductive gate material. It will be understood therefore that in other embodiments the erase gate structure 736 and the control gate structures 740 can be formed of a material that is different from a material of the sacrificial gate structures 716s. Further, the material that forms the sacrificial gate structures 716s can be a sacrificial material that is non-conductive, e.g., amorphous silicon or the like. Further, the conductive material that forms the erase gate structure 736 can be different from the material that forms the control gate structures 740 and can be other than polysilicon, e.g., a metal or metal-containing material including one or more of aluminum, cobalt, copper, tungsten, or the like.

The first planarization operation, e.g., CMP, provides an intermediate semiconductor device structure in which upper surfaces of the erase gate structure 736, the control gate structures 740, and the sacrificial gate structures 716s are coplanar, as indicated by a level L7a in FIG. 7A. In some embodiments, the first planarization operation is controlled using a contact etch stop layer (CESL) (not shown in FIG. 7A) to stop the planarization at the level L7a.

In stage S715, a first mask layer M7a, e.g., of a photoresist or the like, is formed to cover the sacrificial gate structures 716s. An opening M7aO in the first mask layer M7a exposes upper surfaces of the erase gate structure 736 and the control gate structures 740. The opening M7aO allows a subsequent etch-back operation to etch-back upper portions of the erase gate structure 736 and the control gate structures 740, to provide for formation of a cap structure thereon.

In stage S720, the etch-back operation removes upper portions of the erase gate structure 736 and the control gate structures 740. The first mask layer M7a protects the sacrificial gate structures 716s during the etch-back operation. The first mask layer M7a is then removed.

In stage S725, a capping material C7a is deposited to fill the etched-back regions over the erase gate structure 736 and the control gate structures 740. In some embodiments, the capping material C7a includes an electrically insulating material. In some embodiments, the capping material C7a is a single layer of material, e.g., a single layer of an electrically insulating material that is or includes one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)).

Referring to FIG. 7B, in stage S730, excess capping material C7a is removed while being allowed to remain in the etched-back regions, as cap structures 738 on the erase gate structure 736 and the control gate structures 740. Stage 730 includes planarizing the capping material C7a using CMP or the like.

In some embodiments, the capping material C7a (and thus the cap structures 738) is selected to be more hydrophilic than the material, e.g., polysilicon, of the erase gate structure 736 and the control gate structures 740. The more-hydrophilic capping material (relative to the material of the erase gate structure 736 and the control gate structures 740) enables more effective and thorough cleaning than would be achieved in the absence of the capping material. In other words, if the etch-back and capping operations were not performed, such that the less-hydrophilic material, e.g., polysilicon, of the erase gate structure 736 and the control gate structures 740 were to be exposed, there would be a greater possibility of retaining particles on the erase gate structure 736 and the control gate structures 740, which could lead to microscratches. Such microscratches could be filled with a conductive material in subsequent stages S745 and/or S765, leading to the possibility of conductive bridging and short-circuits between the erase gate structure 736 and an adjacent control gate structure 740.

As a result of the planarizing operation in stage S730, upper surfaces of the cap structures 738 are coplanar with upper surfaces of the sacrificial gate structures 716s at a level L7b. In some embodiments the level L7b is the same as the level L7a. In other embodiments, the level L7b is lower than the level L7a.

In stage S735, a second mask layer M7b, e.g., of a photoresist or the like, is formed to cover the cap structures 738. A first sacrificial gate structure 716s1 of the sacrificial gate structures 716s is exposed by an opening M7bO in the second mask layer M7b. A second sacrificial gate structure 716s2 of the sacrificial gate structures 716s is covered by the second mask layer M7b. As will be described, in some embodiments a gate that is formed in place of the first sacrificial gate structure 716s1 includes one or more materials that are different from materials of a gate that is formed in place of the second sacrificial gate structure 716s2, e.g., to provide different work functions for P-type and N-type transistor gates or the like. Covering one sacrificial gate structure while exposing the other allows for different gate materials to be formed for different gates.

In stage S740, the first sacrificial gate structure 716s1 is removed, e.g., using an etching operation. The second mask layer M7b is then removed, exposing, among other things, the cap structures 738 on the erase gate structure 736 and the control gate structures 740.

In stage S745, a conductive first gate material G7a is deposited to fill the region where the first sacrificial gate structure 716s1 was removed. The first gate material G7a is also deposited on the cap structures 738 over the erase gate structure 736 and the control gate structures 740. In some embodiments, the first gate material G7a is formed as a single monolithic material layer. In other embodiments, the first gate material G7a includes a plurality of layers of different materials, e.g., work function layers, gate material layers, and the like, which can be preferentially selected for P-type (or N-type) transistors.

Referring to FIG. 7C, in stage S750, excess first gate material G7a is removed while being allowed to remain where the first sacrificial gate structure 716s1 was removed, as a first logic gate structure 716-1. Stage S750 includes planarizing the first gate material G7a using CMP or the like.

As a result of the planarizing operation in stage S750, upper surfaces of the cap structures 738 are coplanar with upper surfaces of the first logic gate structure 716-1 and the second sacrificial gate structure 716s2 at a level L7c. In some embodiments the level L7c is the same as the level L7b. In other embodiments, the level L7c is lower than the level L7b.

In stage S755, a third mask layer M7c, e.g., of a photoresist or the like, is formed to cover the cap structures 738. A second sacrificial gate structure 716s2 of the sacrificial gate structures 716s is exposed by an opening M7cO in the second mask layer M7b. As shown in stage S755, the first logic gate structure 716-1 may also be exposed by an opening in the third mask layer M7c in the case that a subsequent etching operation to remove the second sacrificial gate structure 716s2 is substantially selective toward the second sacrificial gate structure 716s2 such that the first logic gate structure 716-1 is substantially unaffected by the etching operation.

In stage S760, the second sacrificial gate structure 716s2 is removed, e.g., using an etching operation. The third mask layer M7c is then removed, exposing, among other things, the cap structures 738 on the erase gate structure 736 and the control gate structures 740.

In stage S765, a conductive second gate material G7b is deposited to fill the region where the second sacrificial gate structure 716s2 was removed. The second gate material G7b is also deposited on the cap structures 738 over the erase gate structure 736 and the control gate structures 740. In some embodiments, the second gate material G7b is formed as single monolithic material layer. In other embodiments, the second gate material G7b includes a plurality of layers of different materials, e.g., work function layers, gate material layers, and the like, which can be preferentially selected for N-type (or P-type) transistors.

Referring to FIG. 7D, in stage S770, excess second gate material G7b is removed while being allowed to remain where the second sacrificial gate structure 716s2 was removed, as a second logic gate structure 716-2. Stage 770 includes planarizing the second gate material G7b using CMP or the like.

In stage S775, additional structures such as vias 724, word line contact structure 726, and isolation layer 728 are formed. In some embodiments, the result of stage S775 is the semiconductor device 400.

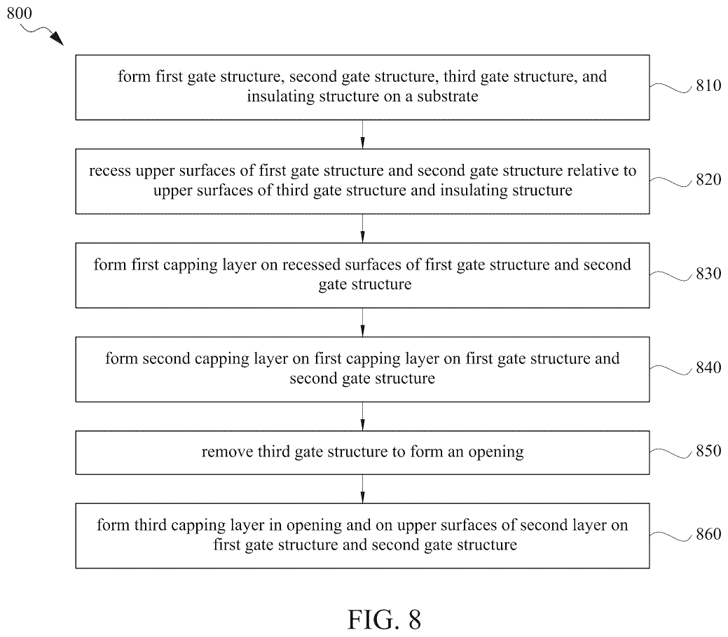

FIG. 8 is a flowchart of a method 800 of fabricating a semiconductor device according to some embodiments.

In FIG. 8, the method 800 includes operations 810, 820, 830, 840, 850, and 860. Although the operations are numbered in sequence, the operations are not to be construed as necessarily requiring their performance in the particular order discussed or illustrated. Moreover, additional or alternative operations can be performed.

Referring to FIG. 8, operation 810 includes forming a first gate structure, a second gate structure, a third gate structure, and an insulating structure on a substrate.

In some embodiments, the substrate is a semiconductor substrate, e.g., a single crystal substrate. In some embodiments, the substrate is a silicon substrate, a silicon-germanium substrate, a silicon carbide substrate, a gallium arsenide substrate, or the like. In some embodiments, the substrate includes silicon and another elemental semiconductor such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate is a semiconductor-on-insulator (SOI) substrate, e.g., a silicon-on-insulator substrate. In some embodiments, the substrate includes a doped epi layer, a gradient semiconductor layer, and/or a semiconductor layer overlying another semiconductor layer of a different type, such as a silicon layer on a silicon germanium layer. In some embodiments, the substrate includes doped regions such as a p-well, an n-well, or both. In some embodiments, the substrate is a dielectric substrate, a sapphire substrate, or the like.

In some embodiments, the first gate structure, the second gate structure, and the third gate structure are formed of a same conductive material. In some embodiments, the first gate structure, the second gate structure, and/or the third gate structure are formed of one or more conductive layers. In some embodiments, the first gate structure, the second gate structure, and the third gate structure are formed of polysilicon or the like. In some embodiments, the first gate structure and/or the second gate structure are formed of a metal or metal-containing layers including one or more of aluminum, cobalt, copper, tungsten, or the like. In some embodiments, the third gate structure is formed of a sacrificial material, e.g., polysilicon, amorphous silicon, or the like.

In some embodiments, the insulating structure includes a single layer of insulating material. In other embodiments, the insulating structure includes two or more layers, e.g., a layer of silicon oxide on a side of the first gate structure, a layer of silicon nitride on a side of the silicon oxide layer, and another layer of silicon nitride on a side of the second gate structure, forming a silicon oxide/silicon nitride/silicon oxide structure between the first gate structure and the second gate structure.

In some embodiments, forming the first gate structure, the second gate structure, the insulating structure, and the third gate structure includes planarizing (e.g., using CMP or the like) upper surfaces of the first gate structure, the second gate structure, the insulating structure, and the third gate structure such that all four of the first gate structure, the second gate structure, the insulating structure, and the third gate structure have upper surfaces that are substantially even with or level with each other.

In some embodiments, the first gate structure, the second gate structure, and the insulating structure are formed in a memory region of the substrate. In some embodiments, the first gate structure, the second gate structure, and the insulating structure are all part of a same memory device, e.g., an NVM memory device such as a split-gate flash memory device or the like. In some embodiments, the first gate structure is an erase gate and the second gate structure is a control gate of the split-gate memory device.

In some embodiments, the third gate structure is in a logic region of the substrate, and is spaced apart from the first and second gate structures. In some embodiments, the third gate structure corresponds to a location of a gate in a transistor that forms a circuit in the logic region.

In some embodiments, operation 810 also includes forming a fourth gate structure as part of the memory device, on an opposite side of the first gate structure from the second gate structure. In some embodiments, the first gate structure corresponds to an erase gate of a split-gate memory device, and the second and fourth gate structures correspond to control gates of the split-gate memory device. In some embodiments, the second and fourth gate structures are formed over respective floating gate structures of the split-gate memory device.

Operation 820 includes recessing upper surfaces of first gate structure and second gate structure relative to upper surfaces of third gate structure and insulating structure.

In some embodiments, a masking layer is deposited and then patterned to form openings at locations in the masking layer corresponding to locations of the first and second gate structures. In some embodiments, the masking layer is or includes a photoresist layer. An etching operation, e.g., an isotropic or anisotropic etching operations such as a wet etch, plasma etch, or the like, is performed to partially remove the first and second gate structures through the openings in the masking layer. In some embodiments, the masking layer includes a single opening that exposes upper surfaces of the first and second gate structures and the insulating structure while covering the third gate structure. In other embodiments, the masking layer is patterned to expose upper surfaces of the first and second gate structures while covering the insulating structure and the third gate structure.

In some embodiments, the etching operation reduces overall height of the first and second gate structures (i.e., height in the z-axis direction) by about 10% of the height of the first gate structure and/or the second gate structure, e.g., about 10% of the height of the shorter one of the first gate structure and the second gate structure. In a particular example, the first gate structure corresponds to an erase gate, the second gate structure corresponds to a control gate, the first gate structure has an overall height that is greater than that of the second gate structure (while having an upper surface that is level with an upper surface of the second gate structure), and an etching operation is performed to recess each of the first gate structure and the second gate structure by about 10% of the overall height of the second (shorter) gate structure.

In some embodiments, a single continuous opening is formed in the masking layer to expose the first gate structure, the second gate structure, and the insulating layer to an etchant, and an etchant (e.g., an isotropic etchant) that is used to recess the first gate structure and the second gate structure is selective towards a material included in the first gate structure and the second gate structure relative to a material included in the insulating structure such that the insulating structure is not removed or is removed at a lesser rate than the first gate structure and the second gate structure. In a particular example, the insulating structure protrudes (in the Z-axis direction) above the first gate structure and the second gate structure following the etching operation. In other embodiments, an anisotropic etching operation is performed to recess the first gate structure and the second gate structure.

In some embodiments, operation 820 also includes recessing the upper surface of the fourth gate structure, e.g., by about 10% of the height of the fourth gate structure.

In some embodiments, the masking layer is removed following the etching operation, e.g., completely removed, or removed from a memory region of the substrate while being allowed to fully or partially remain in a logic region of the substrate.

Operation 830 includes forming a first capping layer on the recessed upper surfaces of first gate structure and second gate structure.

Forming the first capping layer includes depositing a material on the recessed surfaces of the first gate structure and the second gate structure. The first capping layer is deposited on the recessed surfaces of the first and second gate structures without completely replacing the previously-removed portions of the first and second gate structures, such that recesses remain above the first and second gate structures. In some embodiments, the first capping layer is deposited to a same thickness across the entire substrate. In some embodiments, the first capping layer is or includes an electrically insulating material such as one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)).

In some embodiments, operation 830 also includes forming the cap structure on the recessed upper surface of the fourth gate structure.

Operation 840 includes forming a second capping layer on the first capping layer, on recessed upper surfaces of first gate structure and second gate structure.

Forming the second capping layer includes depositing a material on the recessed surfaces of the first gate structure and the second gate structure. The second capping layer is deposited, on the first capping layer, on the recessed surfaces of the first and second gate structures without completely replacing the previously-removed portions of the first and second gate structures, such that recesses remain above the first and second gate structures. In some embodiments, the second capping layer is deposited to a same thickness across the entire substrate. In some embodiments, the second capping layer is an adhesive material that includes one or more of a metal and/or a metal nitride, e.g., titanium, titanium nitride, tantalum, and/or tantalum nitride. In some embodiments, forming the second capping layer includes forming a metal nitride layer on the first capping layer and forming a metal layer on the metal nitride layer, e.g., as a titanium nitride/titanium stack, a tantalum nitride/tantalum stack, or the like. In some embodiments, forming the second capping layer further includes forming an interfacial metal oxide of the metal, e.g., titanium, tantalum, or the like, e.g., in an ordered stack of nitride/oxide/metal, with the nitride being the first-formed layer on the first layer of the insulating material.

In some embodiments, operation 840 also includes forming the second capping layer on the first capping layer on the recessed upper surface of the fourth gate structure.

Operation 850 includes removing the third gate structure to form an opening.

In some embodiments, removing the third gate structure includes forming a masking layer and patterning the masking layer to form an opening at a location in the masking layer corresponding to the location of the third gate structure. The masking layer covers the first and second capping layers on the first and second gate structures. An etching operation, e.g., an isotropic or anisotropic etching operations such as a wet etch, plasma etch, or the like, is performed to remove the third gate structure through the opening in the masking layer.

In some embodiments, operation 850 also includes forming the masking layer to cover the cap structure on the fourth gate structure.

In some embodiments, the masking layer is removed following the etching operation, e.g., completely removed, or removed from the logic region of the substrate while being allowed to fully or partially remain in the memory region of the substrate.

Operation 860 includes forming a conductive material on the second capping layer and in the opening corresponding to the third gate structure.

In some embodiments, the conductive material is or includes a metal, and a replacement metal gate (RMG) is formed in the opening where the third gate structure was removed. In some embodiments, the RMG includes one or more metal or metal-containing layers, e.g., a work function layer including one or more of titanium nitride, tungsten, tantalum, nickel, platinum, ruthenium, molybdenum, aluminum, tungsten nitride, or the like, and a gate material layer including one or more of aluminum, cobalt, copper, tungsten, or the like, where the work function layer is selected from materials that are different from the gate material layer. In some embodiments, prior to forming the RMG, a gate dielectric layer such as a high-k dielectric layer is formed in the opening where the third gate structure was removed. In some embodiments, the high-k dielectric layer includes one or more dielectric materials such as hafnium oxide, hafnium silicon oxide, hafnium silicon oxynitride, hafnium tantalum oxide, hafnium titanium oxide, hafnium zirconium oxide, metal oxides, metal nitrides, metal silicates, transition metal-oxides, transition metal nitrides, transition metal silicates, oxynitrides of metals, metal aluminates, zirconium silicate, zirconium aluminate, zirconium oxide, titanium oxide, aluminum oxide, a hafnium dioxide-alumina alloy, or the like.

In some embodiments, operation 860 includes forming the conductive material after the masking layer is completely removed, such that the conductive material fills the opening where the third gate structure was removed and covers the substrate in the logic and memory regions, thus also covering the second capping layer and completely filling the recesses over the first and second gate structures as a third capping layer. The substrate is then planarized.

In the method 800, a cap structure, which includes the first capping layer, the second capping layer, and the third capping layer, is formed on the first and second gate structures.

When the third capping layer is formed of a same metal that is used in a RMG, the capping layer is harder than polysilicon, and is thus more resistant to scratching than a comparative case in which erase gate and control gate structures of polysilicon are exposed in the memory region.

Further, when the first capping layer is formed of an insulating material, electrical bridging of adjacent, close-tolerance gate structures that may occur as a result of conductive material filling microscratches is overlying layers is prevented, thus helping to prevent short-circuits, e.g., between the first and second gate structures, e.g., between erase gate and control gate structures.

In some embodiments, operations 820 and 830 include recessing the first, second, and fourth gate structures and forming of the cap structure (including the first capping layer, which is or includes an insulator, and the second and third capping layers), on the first, second, and fourth gate structures, which helps to prevent the conductive material layer formed in operation 860 from coming into contact with the material, e.g., polysilicon or the like, of the first and second gate structures and/or the first and fourth gate structures, thus helping to prevent short-circuits, e.g., between the first and second gate structures and/or the first and fourth gate structures.

In another approach, the cap structure is not used on the memory-region gate structures, e.g., on the first and second gate structures or on the first, second, and fourth gate structures. In the other approach, conductive material that is deposited in a RMG-forming operation for the third gate structure in the logic region can also be deposited in microscratches in the memory region e.g., between the first and second gate structures (or between the first and fourth gate structures), and thus possibly form a conductive bridge between the first and second gate structures (or between the first and fourth gate structures) to result in a short-circuit.

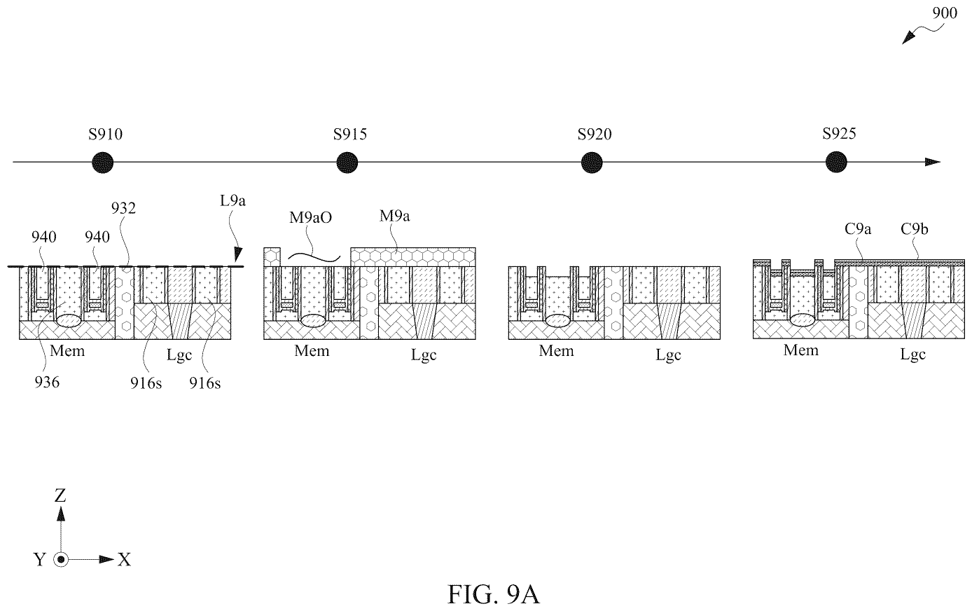

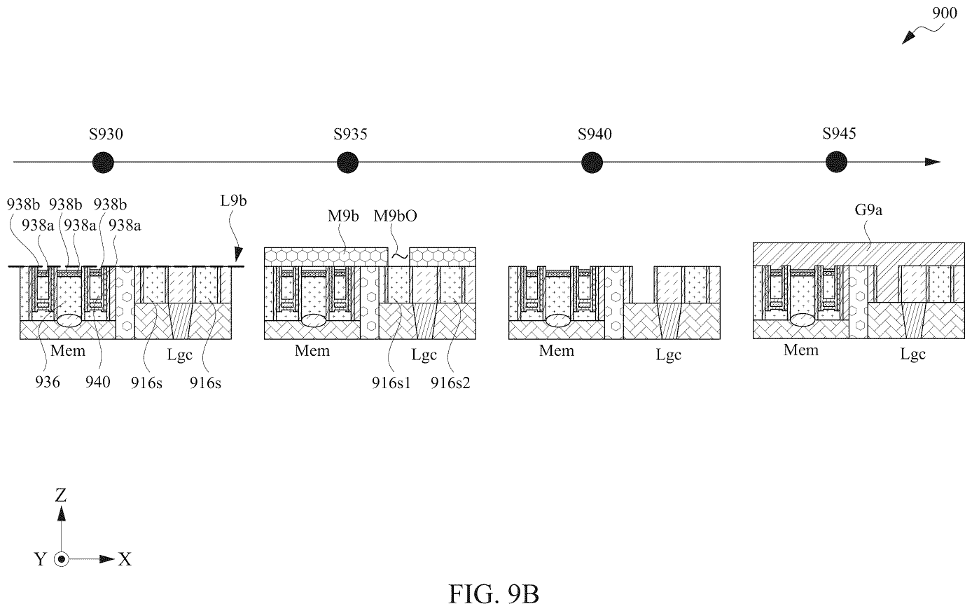

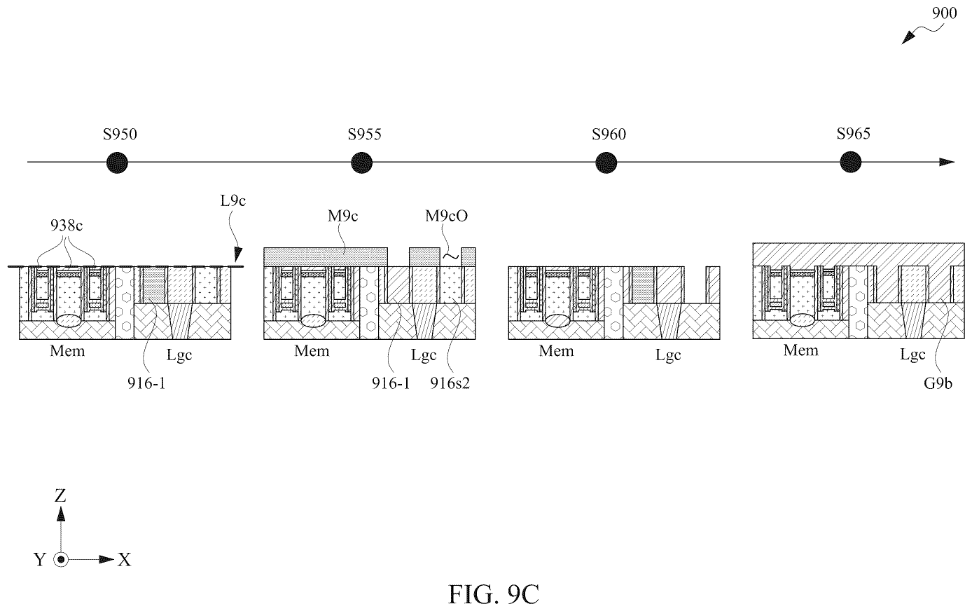

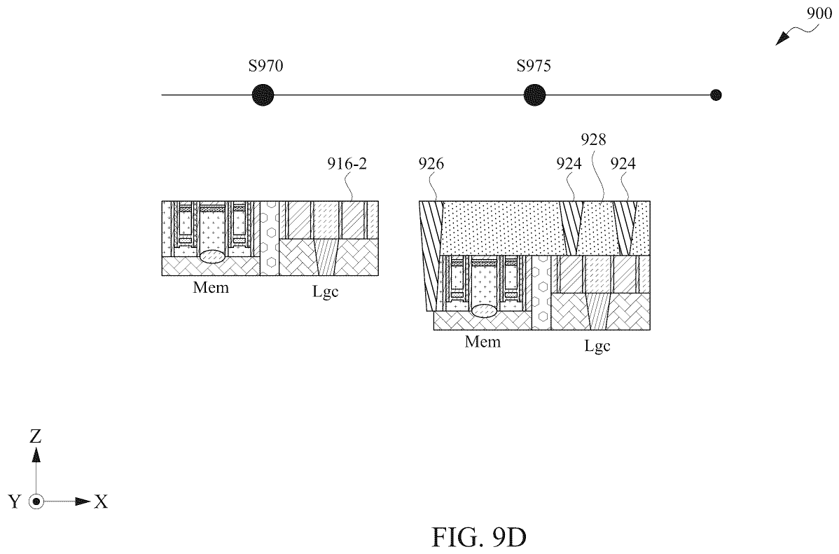

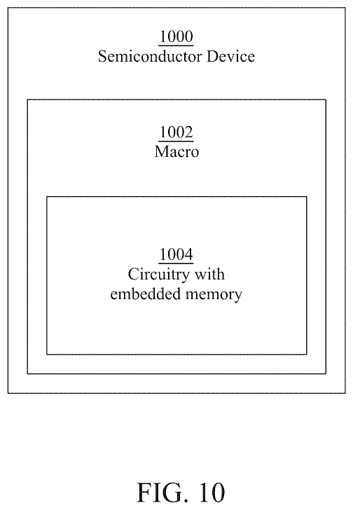

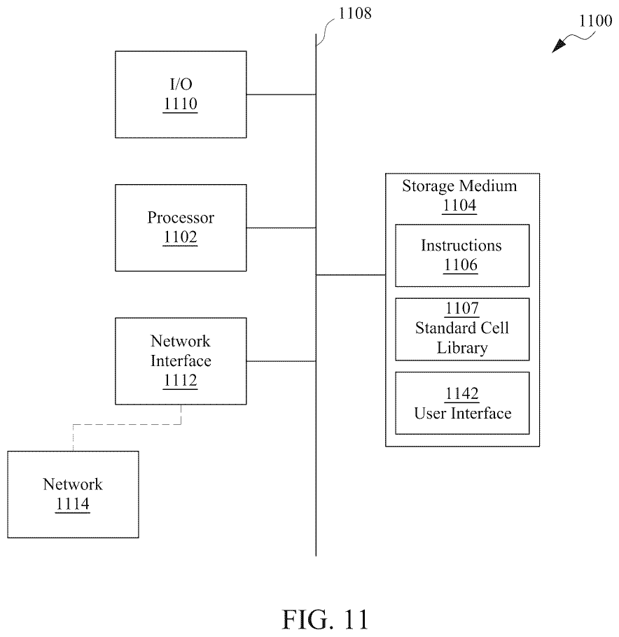

FIGS. 9A, 9B, 9C, and 9D are cross-sectional flow diagrams of stages in a method 900 of fabricating a semiconductor device, e.g., the semiconductor device 500, according to some embodiments.

FIG. 9A includes stages S910, S915, S920, and S925. FIG. 9B includes stages S930, S935, S940, and S945. FIG. 9C includes stages S950, S955, S960, and S965. FIG. 9D includes stages S970 and S975.

Referring to FIG. 9A, in stage S910, a first planarization operation, e.g., CMP or the like, is performed to provide an intermediate semiconductor device structure that includes gate structures in a memory cell (‘Mem’) and gate structures in a logic cell (‘Lgc’) that abut a common dummy structure 932. The memory cell includes an erase gate structure 936 and control gate structures 940. The logic cell includes sacrificial gate structures 916s that correspond to locations where gate structures will be formed in the logic cell, e.g., for P-type and/or N-type transistors in a CMOS circuit.

In FIG. 9A, the erase gate structure 936, the control gate structures 940, and the sacrificial gate structures 916s are formed of a same conductive material, e.g., polysilicon or the like. As will be described, in later stages of the method 900 the sacrificial gate structures 916s are removed and replaced with a conductive gate material. It will be understood therefore that in other embodiments the erase gate structure 936 and the control gate structures 940 can be formed of a material that is different from a material of the sacrificial gate structures 916s. Further, the material that forms the sacrificial gate structures 916s can be a sacrificial material that is non-conductive, e.g., amorphous silicon or the like. Further, the conductive material that forms the erase gate structure 936 can be different from the material that forms the control gate structures 940 and can be other than polysilicon, e.g., a metal or metal-containing material including one or more of aluminum, cobalt, copper, tungsten, or the like.

The first planarization operation, e.g., CMP, provides an intermediate semiconductor device structure in which upper surfaces of the erase gate structure 936, the control gate structures 940, and the sacrificial gate structures 916s are coplanar, as indicated by a level L9a in FIG. 9A. In some embodiments, the first planarization operation is controlled using a contact etch stop layer (CESL) (not shown in FIG. 9A) to stop the planarization at the level L9a.

In stage S915, a first mask layer M9a, e.g., of a photoresist or the like, is formed to cover the sacrificial gate structures 916s. An opening M9aO in the first mask layer M9a exposes upper surfaces of the erase gate structure 936 and the control gate structures 940. The opening M9aO allows a subsequent etch-back operation to etch-back upper portions of the erase gate structure 936 and the control gate structures 940, to provide for formation of a cap structure thereon.

In stage S920, the etch-back operation removes upper portions of the erase gate structure 936 and the control gate structures 940. The first mask layer M9a protects the sacrificial gate structures 916s during the etch-back operation. The first mask layer M9a is then removed.

In stage S925, a first capping material layer C9a and a second capping material layer C9b are sequentially deposited in the etched-back regions over the erase gate structure 936 and the control gate structures 940, without completely filling the etched-back regions.

In some embodiments, the first capping material layer C9a includes an electrically insulating material. In some embodiments, the first capping material layer C9a is a single layer of material, e.g., a single layer of an electrically insulating material that is or includes one or more of a silicon oxide, a silicon nitride, a silicon oxynitride, a phosphosilicate glass (PSG) (e.g., a borophosphosilicate glass, BPSG), or a fluorinated silicate glass (e.g., a fluorinated silicon oxide glass (FSG)).

In some embodiments, the second capping material layer C9b includes is an adhesive material that includes one or more of a metal and/or a metal nitride, e.g., titanium, titanium nitride, tantalum, and/or tantalum nitride. In some embodiments, forming the second capping material layer C9b includes forming a metal nitride layer on the first capping material layer C9a and forming a metal layer on the metal nitride layer, e.g., as a titanium nitride/titanium stack, a tantalum nitride/tantalum stack, or the like. In some embodiments, forming the second capping material layer C9b further includes forming an interfacial metal oxide of the metal, e.g., titanium, tantalum, or the like, e.g., in an ordered stack of nitride/oxide/metal, with the nitride being the first-formed layer on the first capping material layer C9a (the insulating material).

Referring to FIG. 9B, in stage S930, excess first and second capping material layers C9a, C9b are removed while being allowed to remain in the etched-back regions on the erase gate structure 936 and the control gate structures 940, as a first capping layer 938a and a second capping layer 938b. Stage 930 includes planarizing the first and second capping material layers C9a, C9b using CMP or the like. Following the planarizing operation in stage S930, recesses remain below a level L9b at the etched-back regions on the erase gate structure 936 and the control gate structures 940, over the first and second capping layers 938a, 938b.

In stage S935, a second mask layer M9b, e.g., of a photoresist or the like, is formed to cover the first and second capping layers 938a, 938b. A first sacrificial gate structure 916s1 of the sacrificial gate structures 916s is exposed by an opening M9bO in the second mask layer M9b. A second sacrificial gate structure 916s2 of the sacrificial gate structures 916s is covered by the second mask layer M9b. As will be described, in some embodiments a gate that is formed in place of the first sacrificial gate structure 916s1 includes one or more materials that are different from materials of a gate that is formed in place of the second sacrificial gate structure 916s2, e.g., to provide different work functions for P-type and N-type transistor gates or the like. Covering one sacrificial gate structure while exposing the other allows for different gate materials to be formed for different gates.

In stage S940, the first sacrificial gate structure 916s1 is removed, e.g., using an etching operation. The second mask layer M9b is then removed, exposing, among other things, the second capping layer 938b on the erase gate structure 936 and the control gate structures 940.

In stage S945, a conductive first gate material G9a is deposited to fill the region where the first sacrificial gate structure 916s1 was removed. The first gate material G9a is also deposited on the second capping layer 938b over the erase gate structure 936 and the control gate structures 940, completely filling the recesses that were formed by the etch-back operation in stage S920.

In some embodiments, the first gate material G9a is formed as single monolithic material layer. In other embodiments, the first gate material G9a includes a plurality of layers of different materials, e.g., work function layers, gate material layers, and the like, which can be preferentially selected for P-type (or N-type) transistors.

Referring to FIG. 9C, in stage S950, excess first gate material G9a is removed while being allowed to remain where the erase gate structure 936 and the control gate structures 940 were etched-back (as a third capping layer 938c), and where the first sacrificial gate structure 916s1 was removed (as a first logic gate structure 916-1). Stage 950 includes planarizing the first gate material G9a using CMP or the like.

As a result of the planarizing operation in stage S950, upper surfaces of cap structures 938, which include the first, second, and third capping layers 938a, 938b, and 938c, are coplanar with upper surfaces of the first logic gate structure 916-1 and the second sacrificial gate structure 916s2 at a level L9c. In some embodiments the level L9c is the same as the level L9b. In other embodiments, the level L9c is lower than the level L9b.

In stage S955, a third mask layer M9c, e.g., of a photoresist or the like, is formed to cover the third capping layer 938c. A second sacrificial gate structure 916s2 of the sacrificial gate structures 916s is exposed by an opening M9cO in the second mask layer M9b. As shown in stage S955, the first logic gate structure 916-1 may also be exposed by an opening in the third mask layer M9c in the case that a subsequent etching operation to remove the second sacrificial gate structure 916s2 is substantially selective toward the second sacrificial gate structure 916s2 such that the first logic gate structure 916-1 is substantially unaffected by the etching operation.

In stage S960, the second sacrificial gate structure 916s2 is removed, e.g., using an etching operation. The third mask layer M9c is then removed, exposing, among other things, the third capping layer 938c on the erase gate structure 936 and the control gate structures 940.

In stage S965, a conductive second gate material G9b is deposited to fill the region where the second sacrificial gate structure 916s2 was removed. The second gate material G9b is also deposited on the third capping layer 938c over the erase gate structure 936 and the control gate structures 940. In some embodiments, the second gate material G9b is formed as a single monolithic material layer. In other embodiments, the second gate material G9b includes a plurality of layers of different materials, e.g., work function layers, gate material layers, and the like, which can be preferentially selected for N-type (or P-type) transistors.

Referring to FIG. 9D, in stage S970, excess second gate material G9b is removed while being allowed to remain where the second sacrificial gate structure 916s2 was removed, as a second logic gate structure 916-2. Stage 970 includes planarizing the second gate material G9b using CMP or the like.

In stage S975, additional structures such as vias 924, word line contact structure 926, and isolation layer 928 are formed. In some embodiments, the result of stage S975 is the semiconductor device 500.

FIG. 10 is a block diagram of a semiconductor device, according to at least one embodiment.

In FIG. 10, an IC device 1000 includes a macro 1002. In some embodiments, the macro 1002 includes one or more of a memory, a power grid, a cell or cells, an inverter, a latch, a buffer and/or any other type of circuit arrangement that may be represented digitally in a cell library. In some embodiments, the macro 1002 is understood in the context of an analogy to the architectural hierarchy of modular programming, in which subroutines/procedures are called by a main program (or by other subroutines) to carry out a given computational function. In this context, the IC device 1000 uses the macro 1002 to perform one or more given functions. Accordingly, in this context and in terms of architectural hierarchy, the IC device 1000 is analogous to the main program and the macro 1002 is analogous to subroutines/procedures. In some embodiments, the macro 1002 is a soft macro. In some embodiments, the macro 1002 is a hard macro. In some embodiments, the macro 1002 is a soft macro that is described digitally in register-transfer level (RTL) code. In some embodiments, synthesis, placement, and routing have yet to have been performed on the macro 1002 such that the soft macro can be synthesized, placed, and routed for a variety of process nodes. In some embodiments, the macro 1002 is a hard macro that is described digitally in a binary file format (e.g., Graphic Database System II (GDSII) stream format), where the binary file format represents planar geometric shapes, text labels, other information, and the like of one or more layouts of the macro 1002 in hierarchical form. In some embodiments, synthesis, placement, and routing have been performed on the macro 1002 such that the hard macro is specific to a particular process node. In FIG. 10, the macro 1002 includes a region 1004 that includes circuitry with embedded memory, e.g., corresponding to one or more of the semiconductor devices 100, 200, 300, 400, or 500 described above.

FIG. 11 is a block diagram of an electronic design automation (EDA) system 1100 in accordance with some embodiments.

In some embodiments, EDA system 1100 includes an Automatic Place & Route (APR) system. Layouts representing semiconductor devices, e.g., corresponding to one or more of the semiconductor devices 100, 200, 300, 400, or 500 described above, are implementable, for example, using EDA system 1100, according to at least one embodiment.

In some embodiments, EDA system 1100 is a general-purpose computing device including a hardware processor 1102 and a non-transitory, computer-readable storage medium 1104. The computer-readable storage medium 1104, amongst other things, is encoded with, i.e., stores, computer program code 1106, i.e., a set of executable instructions. Execution of instructions 1106 by the processor 1102 represents (at least in part) an EDA tool that implements a portion or all of processes and/or methods for, e.g., synthesis, placement, and routing of a region that includes an NVM, e.g., corresponding one or more of the NVM semiconductor devices described above and/or represented in FIG. 1, in accordance with one or more embodiments (hereinafter, the noted processes and/or methods).

The processor 1102 is electrically coupled to the computer-readable storage medium 1104 via a bus 1108. The processor 1102 is also electrically coupled to an I/O interface 1110 by the bus 1108. A network interface 1112 is also electrically connected to processor 1102 via the bus 1108. Network interface 1112 is connected to a network 1114, so that the processor 1102 and the computer-readable storage medium 1104 are capable of connecting to external elements via network 1114. Processor 1102 is configured to execute computer program code 1106 encoded in the computer-readable storage medium 1104 in order to cause EDA system 1100 to be usable for performing a portion or all of the noted processes and/or methods. In one or more embodiments, processor 1102 is a central processing unit (CPU), a multi-processor, a distributed processing system, an application specific integrated circuit (ASIC), and/or a suitable processing unit.

In one or more embodiments, the computer-readable storage medium 1104 is an electronic, magnetic, optical, electromagnetic, infrared, and/or a semiconductor system (or apparatus or device). Examples of the computer-readable storage medium 1104 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 1104 includes a compact disk read-only memory (CD-ROM), a compact disk-read/write (CD-R/W), and/or a digital video disc (DVD).

In one or more embodiments, the computer-readable storage medium 1104 stores computer program code 1106 configured to cause EDA system 1100 (where such execution represents (at least in part) the EDA tool) to be usable for performing a portion or all of the noted processes and/or methods. In one or more embodiments, the computer-readable storage medium 1104 also stores information that facilitates performing a portion or all of the noted processes and/or methods. In one or more embodiments, the computer-readable storage medium 1104 stores library 1107 of standard cells including such standard cells as disclosed herein.

The EDA system 1100 includes I/O interface 1110. I/O interface 1110 is coupled to external circuitry. In one or more embodiments, I/O interface 1110 includes a keyboard, keypad, mouse, trackball, trackpad, touchscreen, and/or cursor direction keys for communicating information and commands to processor 1102.

The EDA system 1100 also includes network interface 1112 coupled to processor 1102. Network interface 1112 allows EDA system 1100 to communicate with network 1114, to which one or more other computer systems are connected. Network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 is configured to receive information through I/O interface 1110. The information received through I/O interface 1110 includes one or more of instructions, data, design rules, libraries of standard cells, and/or other parameters for processing by processor 1102. The information is transferred to processor 1102 via the bus 1108. EDA system 1100 is configured to receive information related to a user interface (UI) through I/O interface 1110. The information is stored in the computer-readable storage medium 1104 as user interface (UI) 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1100. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

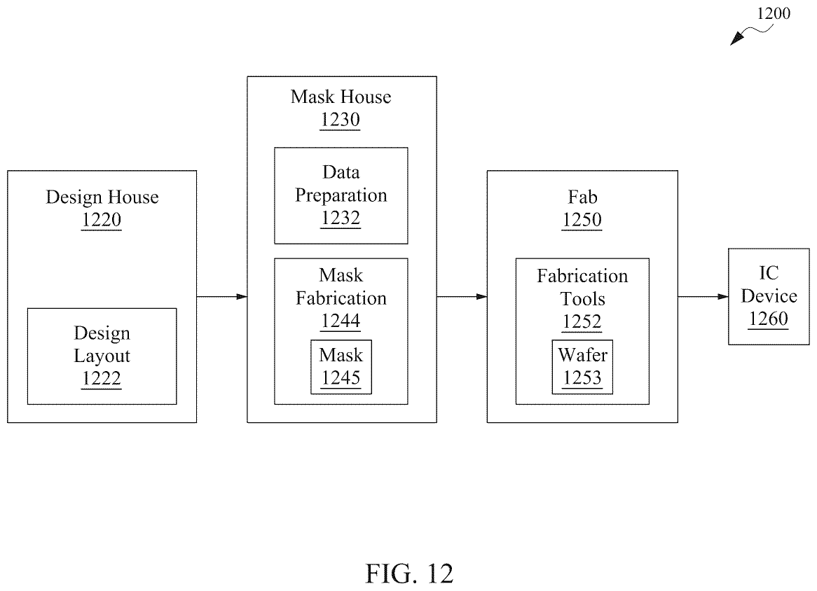

FIG. 12 is a block diagram of an integrated circuit (IC) manufacturing system 1200, and an IC manufacturing flow associated therewith, according to at least one embodiment.

In some embodiments, based on a layout, at least one of (A) one or more semiconductor masks or (B) at least one component in a layer of a semiconductor integrated circuit is fabricated using the IC manufacturing system 1200.

In FIG. 12, the IC manufacturing system 1200 includes entities, such as a design house 1220, a mask house 1230, and an IC manufacturer/fabricator (fab) 1250, that interact with one another in the design, development, and manufacturing cycles and/or services related to manufacturing an IC device 1260, e.g., corresponding to the NVM devices described above with reference to FIG. 1. The entities in the IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1220, the mask house 1230, and the IC fab 1250 are owned by a single larger company. In some embodiments, two or more of the design house 1220, the mask house 1230, and the IC fab 1250 coexist in a common facility and use common resources.

The design house (or design team) 1220 generates an IC design layout 1222. The IC design layout 1222 includes various geometrical patterns designed for an IC device 1260. The geometrical patterns correspond to patterns of metal, oxide, or semiconductor layers that make up the various components of the IC device 1260 to be fabricated. The various layers combine to form various IC features. For example, a portion of the IC design layout 1222 includes various IC features, such as an active region, gate electrode, source and drain, metal lines or vias of an interlayer interconnect, UTM interconnect structure, or the like, passivation layer structures, openings for bonding pads, and conductive bumps to be formed in a semiconductor substrate (such as a silicon wafer) and various material layers disposed on the semiconductor substrate. The design house 1220 implements a formal design procedure to form the IC design layout 1222. The design procedure includes one or more of logic design, physical design or place-and-route operation. The IC design layout 1222 is presented in one or more data files having information of the geometrical patterns. For example, the IC design layout 1222 can be expressed in a GDSII file format or DFII file format.

The mask house 1230 includes mask data preparation 1232 and mask fabrication 1244. The mask house 1230 uses the IC design layout 1222 to manufacture one or more masks 1245 to be used for fabricating the various layers of the IC device 1260 according to the IC design layout 1222. The mask house 1230 performs the mask data preparation 1232, where the IC design layout 1222 is translated into a representative data file (RDF). The mask data preparation 1232 provides the RDF to the mask fabrication 1244. The mask fabrication 1244 includes a mask writer. The mask writer converts the RDF to an image on a substrate, such as a mask (reticle) 1245 or a semiconductor wafer 1253. The IC design layout 1222 is manipulated by the mask data preparation 1232 to comply with particular characteristics of the mask writer and/or requirements of the IC fab 1250. In FIG. 12, the mask data preparation 1232 and the mask fabrication 1244 are illustrated as separate elements. In some embodiments, the mask data preparation 1232 and the mask fabrication 1244 can be collectively referred to as mask data preparation.

In some embodiments, the mask data preparation 1232 includes optical proximity correction (OPC) that uses lithography enhancement techniques to compensate for image errors, such as those that can arise from diffraction, interference, other process effects and the like. The OPC adjusts the IC design layout 1222. In some embodiments, the mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1232 includes a mask rule checker (MRC) that checks the IC design layout 1222 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 1222 to compensate for limitations during the mask fabrication 1244, which may undo part of the modifications performed by OPC in order to meet mask creation rules.

In some embodiments, the mask data preparation 1232 includes lithography process checking (LPC) that simulates processing that will be implemented by the IC fab 1250 to fabricate the IC device 1260. The LPC simulates this processing based on the IC design layout 1222 to create a simulated manufactured device, such as the IC device 1260. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 1222.

It should be understood that the above description of the mask data preparation 1232 has been simplified for the purposes of clarity. In some embodiments, the mask data preparation 1232 includes additional features such as a logic operation (LOP) to modify the IC design layout 1222 according to manufacturing rules. Additionally, the processes applied to the IC design layout 1222 during the mask data preparation 1232 may be executed in a variety of different orders.

After the mask data preparation 1232 and during the mask fabrication 1244, a mask 1245 or a group of masks 1245 are fabricated based on the modified IC design layout 1222. In some embodiments, the mask fabrication 1244 includes performing one or more lithographic exposures based on the IC design layout 1222. In some embodiments, an electron-beam (e-beam) or a mechanism of multiple e-beams is used to form a pattern on a mask (photomask or reticle) 1245 based on the modified IC design layout 1222. The mask 1245 can be formed in various technologies. In some embodiments, the mask 1245 is formed using binary technology. In some embodiments, a mask pattern includes opaque regions and transparent regions. A radiation beam, such as an ultraviolet (UV) beam, used to expose the image sensitive material layer (e.g., photoresist) that has been coated on a wafer, is blocked by the opaque region and transmits through the transparent regions. In one example, a binary mask version of the mask 1245 includes a transparent substrate (e.g., fused quartz) and an opaque material (e.g., chromium) coated in the opaque regions of the binary mask. In another example, the mask 1245 is formed using a phase shift technology. In a phase shift mask (PSM) version of the mask 1245, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1244 is used in a variety of processes. For example, such a mask(s) is used in an ion implantation process to form various doped regions in a semiconductor wafer 1253, in an etching process to form various etching regions in the semiconductor wafer 1253, and/or in other suitable processes.

The IC fab 1250 is an IC fabrication business that includes one or more manufacturing facilities for the fabrication of a variety of different IC products. In some embodiments, the IC fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnect and packaging of the IC products (back-end-of-line (BEOL) fabrication), and a third manufacturing facility may provide other services for the foundry business.

The IC fab 1250 includes fabrication tools 1252 configured to execute various manufacturing operations on semiconductor wafer 1253 such that the IC device 1260 is fabricated in accordance with the mask(s), e.g., the mask 1245. In various embodiments, the fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1250 uses the mask(s) 1245 fabricated by the mask house 1230 to fabricate the IC device 1260. Thus, the IC fab 1250 at least indirectly uses the IC design layout 1222 to fabricate the IC device 1260. In some embodiments, the semiconductor wafer 1253 is fabricated by the IC fab 1250 using the mask(s) 1245 to form the IC device 1260. In some embodiments, the IC fabrication includes performing one or more lithographic exposures based at least indirectly on the IC design layout 1222. The semiconductor wafer 1253 includes a silicon substrate or other proper substrate having material layers formed thereon. The semiconductor wafer 1253 further includes one or more of various doped regions, dielectric features, multilevel interconnects, and the like (formed at subsequent manufacturing steps).

Details regarding an integrated circuit (IC) manufacturing system (e.g., the IC manufacturing system 1200 of FIG. 12), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

In some embodiments, a method of fabricating a semiconductor device includes forming a first gate structure, a second gate structure, a third gate structure, and an insulating structure on a substrate such that the first gate structure, the second gate structure, the third gate structure, and the insulating structure have upper surfaces that are level with each other, wherein the insulating structure is between the first gate structure and the second gate structure; recessing the upper surfaces of the first gate structure and the second gate structure relative to the upper surfaces of the third gate structure and the insulating structure; forming a cap structure on recessed surfaces of the first gate structure and the second gate structure; removing the third gate structure to form an opening; and forming a replacement gate structure in the opening, including forming a conductive material in the opening and on upper surfaces of the cap structure on the first gate structure and the second gate structure.

In some embodiments, a semiconductor device includes a substrate; and a memory device on the substrate, the memory device including: a first gate structure on the substrate; a second gate structure on the substrate adjacent to the first gate in a first direction; an insulating structure on the substrate between the first gate and the second gate relative to the first direction, an upper surface of the insulating structure being higher, relative to the substrate, than an upper surface of the first gate and higher than an upper surface of the second gate; and a cap structure on the upper surface of the first gate and the upper surface of the second gate, wherein an upper surface of the cap structure is substantially level with the upper surface of the insulating structure, and the upper surface of the cap structure is more hydrophilic than the upper surface of the first gate structure and the upper surface of the second gate structure.

In some embodiments, a semiconductor device includes a substrate; a memory structure on the substrate, including: a first gate structure; a second gate structure adjacent to the first gate in a first direction; an insulating structure between the first gate structure and the second gate structure relative to the first direction; and a cap structure on the first gate structure and the second gate structure; and a logic structure on the substrate, including: a third gate structure, wherein the third gate structure has an upper surface that is substantially level with an upper surface of the cap structure, and the upper surface of the cap structure is electrically insulated from the first gate structure and the second gate structure.

It will be appreciated that features, characteristics, and/or elements described in connection with a particular embodiment are usable singly or in combination with features, characteristics, and/or elements described in connection with one or more other embodiments unless otherwise specifically indicated.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, the method comprising:
forming a first gate structure, a second gate structure, a third gate structure, and an insulating structure on a substrate such that the first gate structure, the second gate structure, the third gate structure, and the insulating structure have upper surfaces that are level with each other, wherein the insulating structure is between the first gate structure and the second gate structure;
recessing the upper surfaces of the first gate structure and the second gate structure relative to the upper surfaces of the third gate structure and the insulating structure;
forming a cap structure on recessed surfaces of the first gate structure and the second gate structure;
removing the third gate structure to form an opening; and
forming a replacement gate structure in the opening, including:
forming a conductive material in the opening and on upper surfaces of the cap structure on the first gate structure and the second gate structure.

2. The method of claim 1, wherein:
forming the first gate structure, the second gate structure, and the insulating structure includes:
forming the first gate structure, the second gate structure, and the insulating structure in a memory region of the substrate as parts of a same memory structure, and
forming the third gate structure includes
forming the third gate structure in a logic region of the substrate as part of a logic structure.

3. The method of claim 2, further comprising:
forming a fourth gate structure in the memory region, wherein:
the first gate structure, the second gate structure, the insulating structure, and the fourth gate structure are included in a non-volatile memory cell,
the first gate structure is configured as an erase gate,
the second and fourth gate structures are configured as control gates, and
the third gate structure is configured to control a signal in a logic cell.

4. The method of claim 1, wherein:
the first gate structure and the second gate structure are formed of polysilicon, and
the replacement gate structure is formed of a metal.

5. The method of claim 4, wherein:
the third gate structure is formed in a logic cell in a logic region of the substrate, and
gates in the logic region are formed using a replacement metal gate process.

6. The method of claim 5, further comprising:
forming a fourth gate structure of polysilicon on an opposite side of the first gate structure from the second gate structure, wherein:
the first gate structure, the second gate structure, and the fourth gate structure are included in a non-volatile memory cell in a memory region of the substrate,
the first gate structure is configured as an erase gate,
the second gate structure and the fourth gate structure are configured as control gates, and
the third gate structure is configured to control a signal in the logic cell.

7. The method of claim 6, wherein:
forming the cap structure includes forming the cap structure on a recessed surface of the fourth gate structure, and
an upper surface the cap structure on the first gate structure, the second gate structure, and the fourth gate structure is formed to be coplanar with an upper surface of the conductive material in the opening.

8. The method of claim 1, wherein forming the cap structure includes:
forming at least one capping material layer on the recessed surfaces of the first gate structure and the second gate structure, and on the third gate structure and the insulating structure, and
planarizing the capping material layer to expose the third gate structure and the insulating structure.

9. The method of claim 8, wherein the forming at least one capping material layer includes:
forming an electrically insulating material layer on the recessed surfaces of the first gate structure and the second gate structure;
forming an adhesive material layer on the first gate structure and the second gate structure, over the electrically insulating material layer; and
forming a metal layer on the first gate structure and the second gate structure, over the adhesive material layer.

10. The method of claim 9, wherein forming the conductive material in the opening and forming the metal layer over the adhesive material layer are performed at the same time and include depositing a same metal material.

11. The method of claim 8, wherein the forming at least one capping material layer includes:
forming a first capping material layer that includes one or more of a silicon oxide, a silicon nitride, a silicon oxynitride, a phosphosilicate glass, or a fluorinated silicate glass;
forming a second capping material layer on the first capping material layer, the second capping material layer including one or more of titanium or titanium nitride; and
forming a third capping material layer on the second capping material layer, the third capping material layer including one or more of aluminum or tungsten.

12. The method of claim 1, further comprising:
planarizing the semiconductor device to remove the conductive material from the upper surfaces of the cap structure on the first gate structure and the second gate structure to expose the cap structure on the first gate structure and the second gate structure, and expose the insulating structure between the first gate structure and the second gate structure.

13. A semiconductor device comprising:
a substrate; and
a memory device on the substrate, the memory device including:
a first gate structure on the substrate;
a second gate structure on the substrate adjacent to the first gate in a first direction;
an insulating structure on the substrate between the first gate and the second gate relative to the first direction, an upper surface of the insulating structure being higher, relative to the substrate, than an upper surface of the first gate and higher than an upper surface of the second gate; and
a cap structure on the upper surface of the first gate and the upper surface of the second gate, wherein:
an upper surface of the cap structure is substantially level with the upper surface of the insulating structure, and
the upper surface of the cap structure is more hydrophilic than the upper surface of the first gate structure and the upper surface of the second gate structure.

14. The semiconductor device of claim 13, wherein:
the memory device is a split-gate memory device,
the first gate structure is configured as an erase gate, and
the second gate structure is configured as a control gate.

15. The semiconductor device of claim 13, further comprising:
a logic device, the logic device including a third gate structure on the substrate,
wherein the upper surface of the cap structure is level with an upper surface of the third gate structure.

16. The semiconductor device of claim 13, further comprising:
a logic device, the logic device including a third gate structure on the substrate,
wherein the upper surface of the cap structure is level with an upper surface of the third gate structure and includes a same conductive material as the third gate structure.

17. The semiconductor device of claim 16, wherein:
the upper surface of the cap structure and the third gate structure include a same metal, and
the upper surface of the first gate structure and the upper surface of the second gate structure are polysilicon.

18. A semiconductor device comprising
a substrate;
a memory structure on the substrate, including:
a first gate structure;
a second gate structure adjacent to the first gate in a first direction;
an insulating structure between the first gate structure and the second gate structure relative to the first direction; and
a cap structure on the first gate structure and the second gate structure; and
a logic structure on the substrate, including:
a third gate structure, wherein:
the third gate structure has an upper surface that is substantially level with an upper surface of the cap structure, and
the upper surface of the cap structure is electrically insulated from the first gate structure and the second gate structure.

19. The semiconductor device of claim 18, wherein:
the first gate structure and the second gate structure include polysilicon, and
the upper surface of the cap structure and the third gate structure include a same metal.

20. The semiconductor device of claim 19, wherein:
the memory structure is a split-gate flash memory,
the first gate structure is configured as an erase gate of the split-gate flash memory,
the second gate structure is configured as a control gate of the split-gate flash memory, and
the third gate structure is configured to control a signal in the logic structure.
